(19) United States
(12) Patent Application Publication
(10) Pub. No.: US 2011/0151378 A1
(43) Pub. Date: Jun. 23, 2011

(54) RADIATION-SENSITIVE RESIN COMPOSITION FOR LIQUID IMMERSION LITHOGRAPHY, POLYMER, AND RESIST PATTERN-FORMING METHOD

(75) Inventors: Nobuji MATSUMURA, Tokyo (JP); Akimasa Soyano, Tokyo (JP); Yuusuke Asano, Tokyo (JP); Takehiko Naruoka, Tokyo (JP); Hirokazu Sakakibara, Tokyo (JP); Makoto Shimizu, Tokyo (JP); Yukio Nishimura, Tokyo (JP)

(73) Assignee: JSR Corporation, Tokyo (JP)

(21) Appl. No.: 12/949,790

(22) Filed: Nov. 19, 2010

Related U.S. Application Data
(63) Continuation of application No. PCT/JP2009/059150, filed on May 18, 2009.

(30) Foreign Application Priority Data
May 19, 2008 (JP) 2008-131255
Mar. 25, 2009 (JP) 2009-075039

(51) Int. Cl. G03F 7/004; G03F 7/20; C08F 220/28; C08F 220/22

(52) U.S. Cl. 430/270.1; 430/325; 526/245; 526/246; 526/242; 526/270

(57) ABSTRACT

A radiation-sensitive resin composition for liquid immersion lithography includes a resin component, a photoacid generator and a solvent. The resin component includes an acid-dissociable group-containing resin in an amount of more than 50% by mass. The acid-dissociable group-containing resin includes a repeating unit that includes a fluorine atom and an acid-dissociable group in a side chain of the repeating unit.

### CROSS-REFERENCE TO RELATED APPLICATIONS

The present application is a continuation application of International Application No. PCT/JP2009/059150, filed May 18, 2009, which claims priority to Japanese Patent Application No. 2008-131255, filed May 19, 2008 and Japanese Patent Application No. 2009-075039, filed Mar. 25, 2009. The contents of these applications are incorporated herein by reference in their entirety

### BACKGROUND OF THE INVENTION

1. Field of the Invention

The present invention relates to a radiation-sensitive resin composition for liquid immersion lithography, a polymer, and a resist pattern-forming method.

2. Discussion of the Background

In the field of microfabrication (e.g., production of integrated circuit devices), lithographic technology that enables microfabrication with a line width of 0.10 μm or less has been desired in order to achieve a higher degree of integration. A lithographic process has utilized near ultraviolet rays (e.g., i-line). However, it is difficult to implement sub-quarter-micron microfabrication using near ultraviolet rays. Therefore, use of radiation having a shorter wavelength has been studied to enable microfabrication with a line width of 0.10 μm or less.

Examples of such radiation include deep ultraviolet rays (e.g., mercury line spectrum and excimer laser light), X-rays, electron beams, and the like. In particular, technology that utilizes KrF excimer laser light (wavelength: 248 nm) or ArF excimer laser light (wavelength: 193 nm) has attracted attention.

As a resist that is suitable for excimer laser light, various resists (chemically-amplified resist) that utilize a chemical amplification effect due to an acid-dissociable functional group-containing component and a component that generates an acid upon irradiation (exposure) (hereinafter referred to as “acid generator”) have been proposed.

In order to develop technology that can deal with a reduction in line width of integrated circuit devices, a chemically-amplified resist that responds to short-wavelength radiation (e.g., deep ultraviolet rays), has high transparency to radiation, and exhibits excellent basic performance (e.g., sensitivity, resolution, and pattern profile) has been increasingly desired.

A lithographic process will be required to form a finer pattern (e.g., a fine resist pattern with a line width of about 90 nm). A pattern with a line width of less than 90 nm may be formed by reducing the wavelength of the light source of the exposure system, or increasing the numerical aperture (NA) of the lens.

However, since a new exposure system is required to reduce the wavelength of the light source, the equipment cost increases. When increasing the numerical aperture (NA) of the lens, since the resolution and the depth of focus have a trade-off relationship, a decrease in depth of focus occurs when increasing the resolution.

In recent years, liquid immersion lithography has been proposed as lithographic technology that can solve the above problems. In liquid immersion lithography, a liquid refractive medium (immersion liquid) (e.g., purified water or fluorine-containing inert liquid) is interposed (at least over the resist film) between the lens and the resist film formed on the substrate during exposure.

According to liquid immersion lithography, the optical space (path) is filled with a liquid (e.g., pure water) having a high refractive index (n) instead of an inert gas (e.g., air or nitrogen) so that the resolution can be increased without causing a decrease in depth of focus in the same manner as in the case of using a short-wavelength light source or a high NA lens. A resist pattern that exhibits excellent resolution and an excellent depth of focus can be inexpensively formed by liquid immersion lithography using a lens provided in an existing system. A polymer, an additive, and the like for forming a resist used for liquid immersion lithography have been proposed (see WO2004/068242, Japanese Patent Application Publication (KOKAI) No. 2005-173474, and Japanese Patent Application Publication (KOKAI) No. 2007-163606, for example).

However, liquid immersion lithography has a problem in that the acid generator and the like are eluted from the resist film since the resist film directly comes in contact with the immersion liquid (e.g., water) during exposure. If the elution volume is large, the lens may be damaged, or the desired pattern shape or sufficient resolution may not be obtained.

When using water as the immersion liquid, if the receding contact angle formed by the resist film and water is low, the immersion liquid may drip from the edge of the wafer during high-speed scanning exposure, or development defects such as watermark defects (i.e., a watermark remains) or blob defects (i.e., the solubility of the resist film decreases due to water permeation so that the pattern locally remains unresolved (i.e., an excellent pattern shape is not obtained)) may occur.

Moreover, the receding contact angle formed by the resist film and water is not necessarily sufficient when using a resist including the resin and the additive disclosed in WO2004/068242, Japanese Patent Application Publication (KOKAI) No. 2005-173474, and Japanese Patent Application Publication (KOKAI) No. 2007-163606. If the receding contact angle is low, the immersion liquid (e.g., water) may drip from the edge of the wafer during high-speed scanning exposure, or development defects such as watermark defects may occur. Furthermore, elution of the acid generator and the like into water is not necessarily sufficiently suppressed. In particular, when using a system obtained by mixing components that differ in dissolution behavior (see Japanese Patent Application Publication (KOKAI) No. 2007-163606), the pattern shape after development varies.

### SUMMARY OF THE INVENTION

According to one aspect of the present of the invention, a radiation-sensitive resin composition for liquid immersion lithographyincludes a resin component, a photoacid generator; and a solvent. The resin component includes an acid-dissociable group-containing resin in an amount of more than 50% by mass. The acid-dissociable group-containing resin includes a repeating unit that includes a fluorine atom and an acid-dissociable group in a side chain of the repeating unit.

According to another aspect of the present of the invention, a resist pattern-forming method includes forming a photoresist film on a substrate using the above radiation-sensitive resin composition. The photoresist film is subjected to liquid immersion lithography. The photoresist film subjected to liquid immersion lithography is developed to form a resist pattern.

According to further aspect of the present of the invention, a polymer includes a first repeating unit shown by a following formula (1), and a second repeating unit that includes a lactone skeleton,

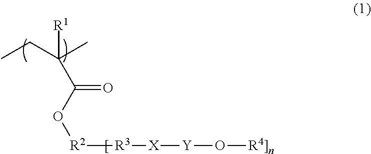

wherein n is an integer from 1 to 3, R¹ represents a hydrogen atom, a methyl group, or a trifluoromethyl group, R² represents a single bond or a linear, branched, or cyclic saturated or unsaturated (n+1)-valent hydrocarbon group having 1 to 10 carbon atoms, R³ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, Y represents a single bond or —CO—, and R⁴ represents an acid-dissociable group when n is 1, or individually represent a hydrogen atom or an acid-dissociable group when n is 2 or 3, provided that at least one of R⁴ represents an acid-dissociable group.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a view schematically showing a state in which an 8-inch silicon wafer is placed on a silicone rubber sheet so that leakage of ultrapure water does not occur when measuring the elution volume from a film formed using a radiation-sensitive resin composition; and

FIG. 2 is a cross-sectional view showing a state when measuring the elution volume from a film formed using a radiation-sensitive resin composition.

### DESCRIPTION OF THE EMBODIMENTS

The embodiments of the invention are described with reference to the accompanying drawings, wherein like reference numerals designate corresponding or identical elements throughout the various drawings. Note that the invention is not limited to the following embodiments. Various modifications, improvements, and the like may be appropriately made of the design without departing from the scope of the invention based on common knowledge of a person skilled in the art.

Note that the term “(meth)acryl” used herein refers to acryl and methacryl. The term “(meth)acrylate” used herein refers to an acrylate and a methacrylate. The term “(meth)acryloyl” used herein refers to acryloyl and methacryloyl.

### [1] Radiation-Sensitive Resin Composition for Liquid Immersion Lithography

A radiation-sensitive resin composition for liquid immersion lithography (hereinafter may be referred to as “radiation-sensitive resin composition”) according to one embodiment of the invention includes (A) a resin component, (B) a photoacid generator, and (C) a solvent.

### <Resin Component (A)>

The resin component (hereinafter may be referred to as “resin component (A)”) includes (A1) an acid-dissociable group-containing resin including (a1) a repeating unit that includes a fluorine atom and an acid-dissociable group in its side chain (hereinafter may be referred to as “resin (A1)”).

Since the radiation-sensitive resin composition includes the resin (A1) including the repeating unit (a1) as the resin component (A), swelling due to a developer can be suppressed while improving the pattern collapse resistance. Specifically, the minimum collapse dimensions can be improved.

The resin (A1) is an acid-dissociable group-containing resin that is insoluble or scarcely soluble in alkali, but becomes alkali-soluble upon dissociation of the acid-dissociable group.

The expression “insoluble or scarcely soluble in alkali” means that a film that is formed only of the resin (A1) has a thickness equal to or more than 50% of the initial thickness when developed under alkaline development conditions employed when forming a resist pattern using a photoresist film that is formed of a radiation-sensitive resin composition that includes the resin component (A).

The repeating unit (a1) is not particularly limited insofar as the repeating unit (a1) includes a fluorine atom and an acid-dissociable group in its side chain. For example, the repeating unit (a1) is preferably a repeating unit shown by the following general formula (1).

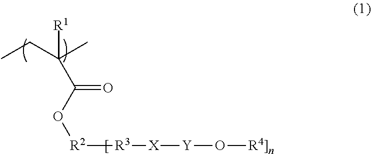

wherein n is an integer from 1 to 3, R¹ represents a hydrogen atom, a methyl group, or a trifluoromethyl group, R² represents a single bond or a linear, branched, or cyclic saturated or unsaturated (n+1)-valent hydrocarbon group having 1 to 10 carbon atoms, R³ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, Y represents a single bond or —CO—, and R⁴ represents an acid-dissociable group when n is 1, or individually represent a hydrogen atom or an acid-dissociable group when n is 2 or 3, provided that at least one of R⁴ represents an acid-dissociable group.

Examples of the linear or branched saturated or unsaturated divalent (n=1) hydrocarbon group having 1 to 10 carbon atoms represented by R² in the general formula (1) include divalent hydrocarbon groups derived from a linear or branched alkyl group having 1 to 10 carbon atoms (e.g., methyl group, ethyl group, n-propyl group, i-propyl group, n-butyl group, 2-methylpropyl group, 1-methylpropyl group, t-butyl group, pentyl group, isopentyl group, neopentyl group, hexyl group, heptyl group, octyl group, nonyl group, and decyl group), and the like.

Examples of the cyclic saturated or unsaturated divalent (n=1) hydrocarbon group represented by R² in the general formula (1) include groups derived from an alicyclic hydrocarbon and an aromatic hydrocarbon having 3 to 10 carbon atoms.

Examples of the alicyclic hydrocarbon include cycloalkanes such as cyclobutane, cyclopentane, cyclohexane, bicyclo[2.2.1]heptane, bicyclo[2.2.2]octane, tricyclo[5.2.1.0^{2,6}]decane, and tricyclo[3.3.1.1^{3,7}]decane, and the like.

Examples of the aromatic hydrocarbon include benzene, naphthalene, and the like.

The hydrocarbon group represented by R² may be a group obtained by substituting at least one hydrogen atom of the unsubstituted hydrocarbon group with at least one of a linear, branched, or cyclic alkyl group having 1 to 4 carbon atoms, such as a methyl group, an ethyl group, an n-propyl group, an i-propyl group, an n-butyl group, a 2-methylpropyl group, a 1-methylpropyl group, or a t-butyl group, a hydroxyl group, a cyano group, a hydroxyalkyl group having 1 to 10 carbon atoms, a carboxyl group, an oxygen atom, and the like.

Examples of the trivalent (n=2) hydrocarbon group represented by R² include groups obtained by elimination of one hydrogen atom from the above divalent hydrocarbon group. Examples of the tetravalent (n=3) hydrocarbon group represented by R² include groups obtained by elimination of two hydrogen atoms from the above divalent hydrocarbon group.

Examples of the linear or branched saturated or unsaturated divalent hydrocarbon group having 1 to 20 carbon atoms represented by R³ in the general formula (1) include divalent hydrocarbon groups derived from a linear or branched alkyl group having 1 to 20 carbon atoms (e.g., methyl group, ethyl group, n-propyl group, i-propyl group, n-butyl group, 2-methylpropyl group, 1-methylpropyl group, t-butyl group, pentyl group, isopentyl group, neopentyl group, hexyl group, heptyl group, octyl group, nonyl group, and decyl group), and the like.

Examples of the cyclic saturated or unsaturated divalent hydrocarbon group represented by R³ in the general formula (1) include groups derived from an alicyclic hydrocarbon and an aromatic hydrocarbon having 3 to 20 carbon atoms.

Examples of the alicyclic hydrocarbon include cycloalkanes such as cyclobutane, cyclopentane, cyclohexane, bicyclo[2.2.1]heptane, bicyclo[2.2.2]octane, tricyclo[5.2.1.0^{2,6}]decane, tricyclo[3.3.1.1^{3,7}]decane, and tetracyclo[6.2.1.1^{3,6}.0^{2,7}]dodecane, and the like.

Examples of the aromatic hydrocarbon include benzene, naphthalene, and the like.

The hydrocarbon group represented by R³ may be a group obtained by substituting at least one hydrogen atom of the unsubstituted hydrocarbon group with at least one of a linear, branched, or cyclic alkyl group having 1 to 12 carbon atoms, such as a methyl group, an ethyl group, an n-propyl group, an i-propyl group, an n-butyl group, a 2-methylpropyl group, a 1-methylpropyl group, or a t-butyl group, a hydroxyl group, a cyano group, a hydroxyalkyl group having 1 to 10 carbon atoms, a carboxyl group, an oxygen atom, and the like.

When n in the general formula (1) is 2 or 3, the groups represented by R³ may be either the same or different.

The acid-dissociable group represented by R⁴ in the general formula (1) refers to a group that substitutes a hydrogen atom of an acidic functional group such as a hydroxyl group, a carboxyl group, or a sulfonic acid group, and dissociates in the presence of an acid.

Examples of the acid-dissociable group include a t-butoxycarbonyl group, a tetrahydropyranyl group, a tetrahydrofuranyl group, a (thiotetrahydropyranylsulfanyl)methyl group, a (thiotetrahydrofuranylsulfanyl)methyl group, an alkoxy-substituted methyl group, an alkylsulfanyl-substituted methyl group, and the like.

Examples of the substituent for the alkoxy-substituted methyl group include alkoxy groups having 1 to 4 carbon atoms. Examples of the substituent for the alkylsulfanyl-substituted methyl group include alkyl groups having 1 to 4 carbon atoms.

Further examples of the acid-dissociable group include a group shown by the general formula “—C(R)₃” (wherein R individually represent a linear or branched alkyl group having 1 to 4 carbon atoms, a monovalent alicyclic hydrocarbon group having 4 to 20 carbon atoms, or a group derived therefrom, or two of R bond to form a divalent alicyclic hydrocarbon group having 4 to 20 carbon atoms, or a group derived therefrom, together with the carbon atom that is bonded thereto, and the remaining R represents a linear or branched alkyl group having 1 to 4 carbon atoms, a monovalent alicyclic hydrocarbon group having 4 to 20 carbon atoms, or a group derived therefrom).

Examples of the linear or branched alkyl group having 1 to 4 carbon atoms represented by R in the acid-dissociable group shown by the general formula “—C(R)3” include a methyl group, an ethyl group, an n-propyl group, an i-propyl group, an n-butyl group, a 2-methylpropyl group, a 1-methylpropyl group, a t-butyl group, and the like.

Examples of the monovalent alicyclic hydrocarbon group having 4 to 20 carbon atoms represented by R include a group that includes an alicyclic ring derived from a cycloalkane (e.g., norbornane, tricyclodecane, tetracyclododecane, adamantane, cyclobutane, cyclopentane, cyclohexane, cycloheptane, or cyclooctane), and the like.

Examples of a group derived from the alicyclic hydrocarbon group include a group obtained by substituting the monovalent alicyclic hydrocarbon group with at least one linear, branched, or cyclic alkyl group having 1 to 4 carbon atoms, such as a methyl group, an ethyl group, an n-propyl group, an i-propyl group, an n-butyl group, a 2-methylpropyl group, a 1-methylpropyl group, or a t-butyl group, and the like.

Among these, an alicyclic hydrocarbon group that includes an alicyclic ring derived from norbornane, tricyclodecane, tetracyclododecane, adamantane, cyclopentane, or cyclohexane, a group obtained by substituting the alicyclic hydrocarbon group with the above alkyl group, and the like are preferable.

Examples of the divalent alicyclic hydrocarbon group having 4 to 20 carbon atoms that is formed by two of R together with the carbon atom that is bonded thereto (i.e., the carbon atom bonded to the oxygen atom) include monocyclic hydrocarbon groups such as a cyclobutylene group, a cyclopentylene group, a cyclohexylene group, and a cyclooctylene group, polynuclear hydrocarbon groups such as a norbornylane group, a tricyclodecanylene group, and a tetracyclodecanylene group, and crosslinked polycyclic hydrocarbon groups such as an adamantylene group.

Examples of a group derived from the divalent alicyclic hydrocarbon group formed by two of R include a group obtained by substituting the divalent alicyclic hydrocarbon group with at least one linear, branched, or cyclic alkyl group having 1 to 4 carbon atoms, such as a methyl group, an ethyl group, an n-propyl group, an i-propyl group, an n-butyl group, a 2-methylpropyl group, a 1-methylpropyl group, or a t-butyl group, and the like.

Among these, monocyclic hydrocarbon groups such as a cyclopentylene group and a cyclohexylene group, a group obtained by substituting the divalent alicyclic hydrocarbon group (monocyclic hydrocarbon group) with the above alkyl group, and the like are preferable.

Preferable examples of the acid-dissociable group shown by the general formula “—C(R)₃” include a t-butyl group, a 1-n-(1-ethyl-1-methyl)propyl group, a 1-n-(1,1-dimethyl)propyl group, a 1-n-(1,1-dimethyl)butyl group, a 1-n-(1,1-dimethyl)pentyl group, 1-(1,1-diethyl)propyl group, a 1-n-(1,1-diethyl)butyl group, a 1-n-(1,1-diethyl)pentyl group, a 1-(1-methyl)cyclopentyl group, a 1-(1-ethyl)cyclopentyl group, a 1-(1-n-propyl)cyclopentyl group, a 1-(1-i-propyl)cyclopentyl group, a 1-(1-methyl)cyclohexyl group, a 1-(1-ethyl)cyclohexyl group, a 1-(1-n-propyl)cyclohexyl group, a 1-(1-i-propyl)cyclohexyl group, a 1-{1-methyl-1-(2-norbornyl)}ethyl group, a 1-{1-methyl-1-(2-tetracyclodecanyl)}ethyl group, a 1-{1-methyl-1-(1-adamantyl)}ethyl group, a 2-(2-methyl)norbornyl group, a 2-(2-ethyl)norbornyl group, a 2-(2-n-propyl)norbornyl group, a 2-(2-i-propyl)norbornyl group, a 2-(2-methyl)tetracyclodecanyl group, a 2-(2-ethyl)tetracyclodecanyl group, a 2-(2-n-propyl)tetracyclodecanyl group, a 2-(2-i-propyl)tetracyclodecanyl group, a 1-(1-methyl)adamantyl group, a 1-(1-ethyl)adamantyl group, a 1-(1-n-propyl)adamantyl group, a 1-(1-i-propyl)adamantyl group, a group obtained by substituting the above group with at least one linear, branched, or cyclic alkyl group having 1 to 4 carbon atoms, such as a methyl group, an ethyl group, a n-propyl group, an i-propyl group, an n-butyl group, a 2-methylpropyl group, a 1-methylpropyl group, or a t-butyl group, and the like.

Among these, the group shown by the general formula “—C(R)₃”, a t-butoxycarbonyl group, an alkoxy-substituted methyl group, and the like are preferable. In particular, a t-butoxycarbonyl group or an alkoxy-substituted methyl group is preferable (1) when protecting a hydroxyl group, and the group shown by the general formula “—C(R)₃” is preferable (2) when protecting a carboxyl group.

Examples of the methylene group substituted with a fluorine atom or the linear or branched fluoroalkylene group having 2 to 20 carbon atoms represented by X include the structures shown by the following formulas (X-1) to (X-8).

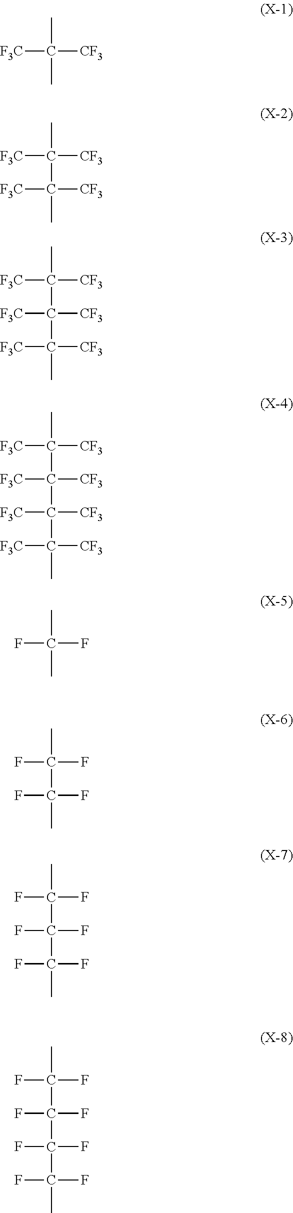

Examples of the repeating unit shown by the general formula (1) include a repeating unit shown by the following general formula (1-1).

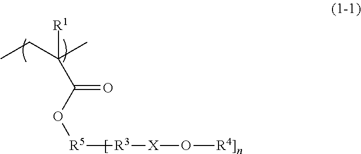

wherein n is an integer from 1 to 3, R¹ represents a hydrogen atom, a methyl group, or a trifluoromethyl group, R³ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, R⁴ represents an acid-dissociable group when n is 1, or individually represent a hydrogen atom or an acid-dissociable group when n is 2 or 3, provided that at least one of R⁴ represents an acid-dissociable group, and R⁵ represents a linear, branched, or cyclic saturated or unsaturated (n+1)-valent hydrocarbon group having 3 to 10 carbon atoms.

The description given above in connection with R³, R⁴, and X in the general formula (1) is applied to R³, R⁴, and X in the general formula (1-1).

Examples of the linear or branched saturated or unsaturated divalent (n=1) hydrocarbon group having 3 to 10 carbon atoms represented by R⁵ in the general formula (1-1) include divalent hydrocarbon groups derived from a linear or branched alkyl group having 3 to 10 carbon atoms (e.g., n-propyl group, i-propyl group, n-butyl group, 2-methylpropyl group, 1-methylpropyl group, t-butyl group, pentyl group, isopentyl group, neopentyl group, hexyl group, heptyl group, octyl group, nonyl group, and decyl group), and the like.

Examples of the cyclic saturated or unsaturated divalent (n=1) hydrocarbon group represented by R⁵ in the general formula (1-1) include groups derived from an alicyclic hydrocarbon and an aromatic hydrocarbon having 3 to 10 carbon atoms.

Examples of the alicyclic hydrocarbon include cycloalkanes such as cyclobutane, cyclopentane, cyclohexane, bicyclo[2.2.1]heptane, bicyclo[2.2.2]octane, tricyclo[5.2.1.0^{2,6}]decane, and tricyclo[3.3.1.1^{3,7}]decane, and the like.

Examples of the aromatic hydrocarbon include benzene, naphthalene, and the like.

The hydrocarbon group represented by R⁵ may be a group obtained by substituting at least one hydrogen atom of the unsubstituted hydrocarbon group with at least one of a linear, branched, or cyclic alkyl group having 1 to 4 carbon atoms, such as a methyl group, an ethyl group, an n-propyl group, an i-propyl group, an n-butyl group, a 2-methylpropyl group, a 1-methylpropyl group, or a t-butyl group, a hydroxyl group, a cyano group, a hydroxyalkyl group having 1 to 10 carbon atoms, a carboxyl group, an oxygen atom, and the like.

Examples of the trivalent (n=2) hydrocarbon group represented by R⁵ include groups obtained by elimination of one hydrogen atom from the above divalent hydrocarbon group. Examples of the tetravalent (n=3) hydrocarbon group represented by R⁵ include groups obtained by elimination of two hydrogen atoms from the above divalent hydrocarbon group.

The repeating unit shown by the general formula (1-1) is preferably any of repeating units shown by the following general formulas (1-1a) to (1-1f), and more preferably a repeating unit shown by the following general formula (1-1d-1).

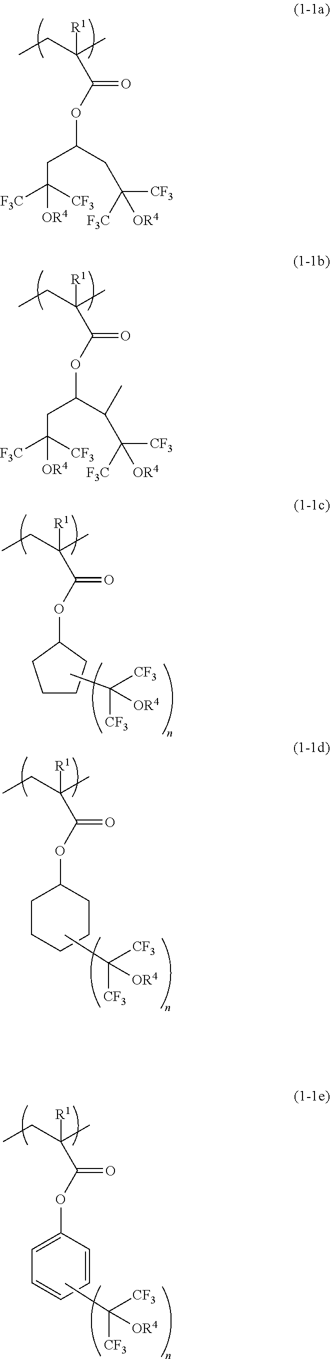

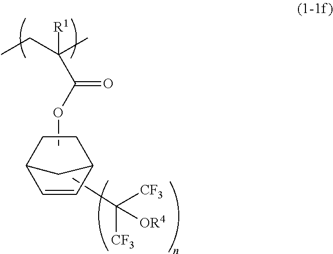

wherein n is an integer from 1 to 3, R¹ represents a hydrogen atom, a methyl group, or a trifluoromethyl group, R⁴ represents an acid-dissociable group when n is 1, or individually represent a hydrogen atom or an acid-dissociable group when n is 2 or 3, provided that at least one of R⁴ represents an acid-dissociable group.

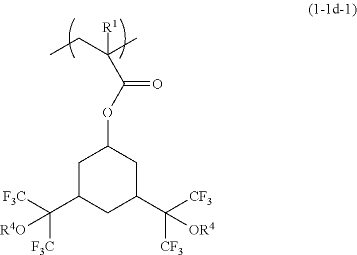

wherein R⁴ individually represent a hydrogen atom or an acid-dissociable group, provided that at least one of R⁴ represents an acid-dissociable group.

The description given above in connection with R⁴ in the general formula (1) is applied to R⁴ in the general formulas (1-1a) to (1-1f) and (1-1d-1).

Further examples of the repeating unit shown by the general formula (1) include a repeating unit shown by the following general formula (1-2).

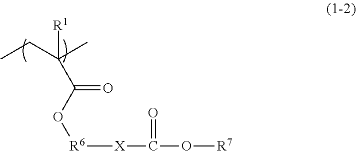

wherein R¹ represents a hydrogen atom, a methyl group, or a trifluoromethyl group, R⁶ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, and R⁷ represents an acid-dissociable group.

The description given above in connection with X, R³, and R⁴ (acid-dissociable group) in the general formula (1) is applied to X, R⁶, and R⁷ in the general formula (1-2).

Specific examples of the group represented by R⁶ in the general formula (1-2) include groups having the following structures (a1) to (a27) and the like. Note that “*” in the structures (a1) to (a27) indicates a bonding site.

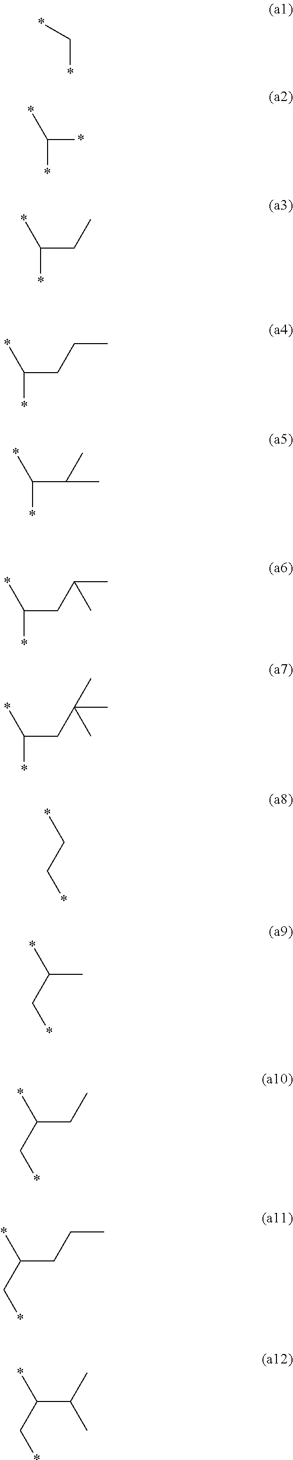

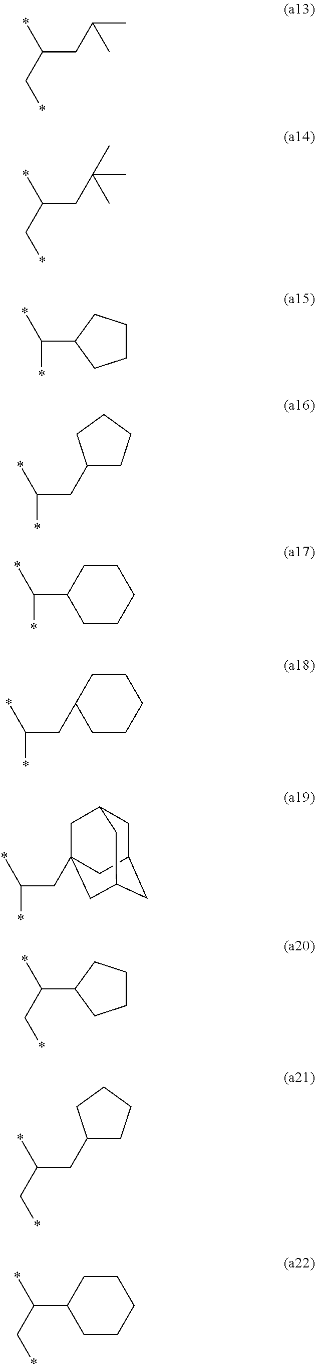

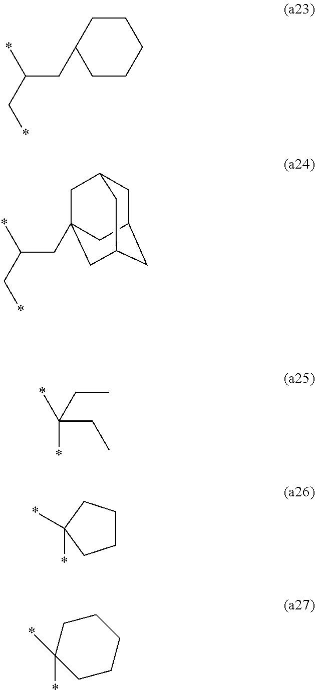

R⁶ in the general formula (1-2) preferably represents a methylene group, an ethylene group, a 1-methylethylene group, a 2-methylethylene group, a divalent alicyclic hydrocarbon group having 4 to 20 carbon atoms, a group derived therefrom, or the like.

R⁷ in the general formula (1-2) preferably represents a t-butoxycarbonyl group, an alkoxy-substituted methyl group, the group shown by the general formula “—C(R)₃”, or the like.

Further examples of the repeating unit shown by the general formula (1) include a repeating unit shown by the following general formula (1-3).

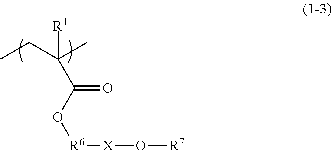

wherein R¹ represents a hydrogen atom, a methyl group, or a trifluoromethyl group, R⁶ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, and R⁷ represents an acid-dissociable group.

The description given above in connection with X and R⁴ (acid-dissociable group) in the general formula (1) is applied to X and R⁷ in the general formula (1-3). The description given above in connection with R⁶ in the general formula (1-2) is applied to R⁶ in the general formula (1-3).

The resin (A1) may include only one type of repeating unit (a1) shown by the general formula (1), or may include two or more types of repeating unit (a1) shown by the general formula (1).

The content of the repeating unit (a1) is preferably 3 to 50 mol %, and more preferably 5 to 30 mol %, based on the total amount (100 mol %) of the repeating units included in the resin (A1). If the content of the repeating unit (a1) is more than 50 mol %, the solubility of the exposed resin (A1) in a developer may be adversely affected, so that the resolution may decrease. If the content of the repeating unit (a1) is less than 3 mol %, the effects the embodiment of the invention may not be obtained.

The resin (A1) preferably further includes a repeating unit that includes an acid-dissociable group (excluding a repeating unit corresponding to the repeating unit (a1)), or a repeating unit that includes a lactone skeleton, a hydroxyl group, a carboxyl group, or the like that improves alkali solubility in addition to the repeating unit (a1).

Examples of the repeating unit that includes an acid-dissociable group (hereinafter referred to as “repeating unit (a2)”) include t-butyl(meth)acrylate, 1-methyl-1-cyclopentyl(meth)acrylate, 1-ethyl-1-cyclopentyl(meth)acrylate, 1-isopropyl-1-cyclopentyl(meth)acrylate, 1-methyl-1-cyclohexyl(meth)acrylate, 1-ethyl-1-cyclohexyl(meth)acrylate, 1-isopropyl-1-cyclohexyl(meth)acrylate, 1-ethyl-1-cyclooctyl(meth)acrylate, 2-methyladamant-2-yl(meth)acrylate, 2-ethyladamant-2-yl(meth)acrylate, 2-n-propyladamant-2-yl(meth)acrylate, 2-isopropyladamant-2-yl(meth)acrylate, 1-(adamantan-1-yl)-1-methylethyl(meth)acrylate, 1-(adamantan-1-yl)-1-ethylethyl(meth)acrylate, 1-(adamantan-1-yl)-1-methylpropyl(meth)acrylate, 1-(adamantan-1-yl)-1-ethylpropyl(meth)acrylate, and the like.

Among these, a monocyclic repeating unit that includes an acid-dissociable group (e.g., 1-methyl-1-cyclopentyl(meth)acrylate, 1-ethyl-1-cyclopentyl(meth)acrylate, 1-isopropyl-1-cyclopentyl(meth)acrylate, 1-methyl-1-cyclohexyl(meth)acrylate, 1-ethyl-1-cyclohexyl(meth)acrylate, 1-isopropyl-1-cyclohexyl(meth)acrylate, and 1-ethyl-1-cyclooctyl(meth)acrylate) is preferable.

The resin (A1) may include only one type of repeating unit (a2), or may include two or more types of repeating unit (a2).

The content of the repeating unit (a2) is preferably 10 to 90 mol %, and more preferably 20 to 80 mol %, based on the total amount (100 mol %) of the repeating units included in the resin (A1). If the content of the repeating unit (a2) is less than 10 mol %, the solubility of the exposed resin (A1) in a developer may be adversely affected, so that the resolution may decrease. If the content of the repeating unit (a2) is more than 80 mol %, adhesion to a substrate may be insufficient.

Examples of a monomer that produces the repeating unit including a lactone skeleton (hereinafter referred to as “repeating unit (a3)”) include repeating units shown by the following general formulas (2-1) to (2-6) and the like.

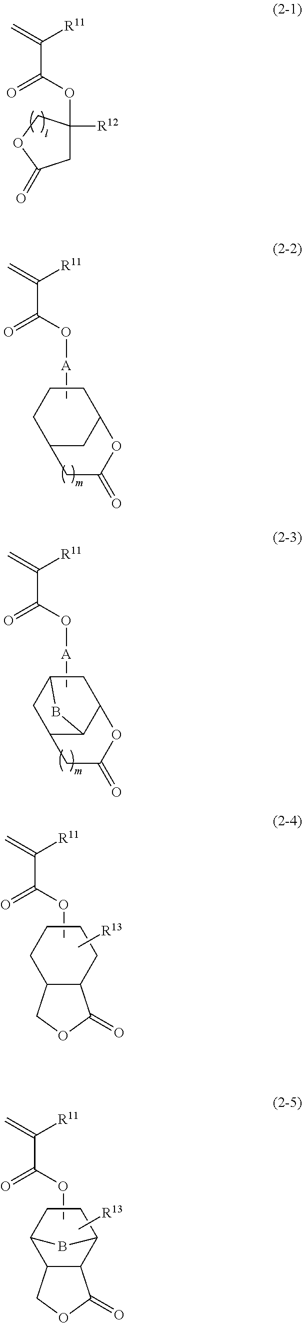

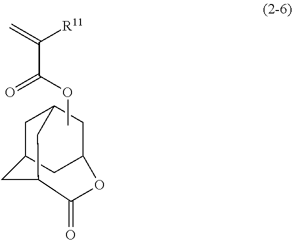

wherein R¹¹ represents a hydrogen atom or a methyl group, R¹² represents a hydrogen atom or a substituted or unsubstituted alkyl group having 1 to 4 carbon atoms, R¹³ represents a hydrogen atom or a methoxy group, A represents a single bond, an ether group, an ester group, a carbonyl group, a divalent chain-like hydrocarbon group having 1 to 30 carbon atoms, a divalent alicyclic hydrocarbon group having 3 to 30 carbon atoms, a divalent aromatic hydrocarbon group having 6 to 30 carbon atoms, or a divalent group that is a combination of these groups, B represents an oxygen atom or a methylene group, 1 is an integer from 1 to 3, and m is 0 or 1.

Examples of the substituted or unsubstituted alkyl group having 1 to 4 carbon atoms represented by R¹² in the general formula (2-1) include a methyl group, an ethyl group, an n-propyl group, an i-propyl group, an n-butyl group, a 2-methylpropyl group, a 1-methylpropyl group, a t-butyl group, and the like.

Examples of the divalent chain-like hydrocarbon group having 1 to 30 carbon atoms represented by A in the general formulas (2-2) and (2-3) include linear alkylene groups such as a methylene group, an ethylene group, a 1,2-propylene group, a 1,3-propylene group, a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, a tetradecamethylene group, a pentadecamethylene group, a hexadecamethylene group, a heptadecamethylene group, an octadecamethylene group, a nonadecamethylene group, and an icosylene group; branched alkylene groups such as a 1-methyl-1,3-propylene group, a 2-methyl-1,3-propylene group, a 2-methyl-1,2-propylene group, a 1-methyl-1,4-butylene group, a 2-methyl-1,4-butylene group, a methylidene group, an ethylidene group, a propylidene group, and a 2-propylidene group; and the like.

Examples of the divalent alicyclic hydrocarbon group having 3 to 30 carbon atoms represented by A in the general formulas (2-2) and (2-3) include monocyclic cycloalkylene groups having 3 to 30 carbon atoms, such as a 1,3-cyclobutylene group, a 1,3-cyclopentylene group, a 1,4-cyclohexylene group, and a 1,5-cyclooctylene group; polycyclic cycloalkylene groups such as a 1,4-norbornylene group, a 2,5-norbornylene group, a 1,5-admantylene group, and a 2,6-admantylene group; and the like.

Examples of the divalent aromatic hydrocarbon group having 6 to 30 carbon atoms represented by A in the general formulas (2-2) and (2-3) include arylene groups such as a phenylene group, a tolylene group, a naphthylene group, a phenanthrylene group, and an anthrylene group, and the like.

Specific examples of a preferable monomer that produces the repeating unit (a3) include 5-oxo-4-oxa-tricyclo[4.2.1.0^{3,7}]non-2-yl(meth)acrylate, 9-methoxycarbonyl-5-oxo-4-oxa-tricyclo[4.2.1.0^{3,7}]non-2-yl(meth)acrylate, 5-oxo-4-oxa-tricyclo[5.2.1.0^{3,8}]dec-2-yl(meth)acrylate, 10-methoxycarbonyl-5-oxo-4-oxatricyclo[5.2.1.0^{3,8}]non-2-yl(meth)acrylate, 6-oxo-7-oxa-bicyclo[3.2.1]oct-2-yl(meth)acrylate, 4-methoxycarbonyl-6-oxo-7-oxa-bicyclo[3.2.1]oct-2-yl(meth)acrylate, 7-oxo-8-oxa-bicyclo[3.3.1]oct-2-yl(meth)acrylate, 4-methoxycarbonyl-7-oxo-8-oxa-bicyclo[3.3.1]oct-2-yl(meth)acrylate, 2-oxo-tetrahydropyran-4-yl(meth)acrylate, 4-methyl-2-oxo-tetrahydropyran-4-yl(meth)acrylate, 4-ethyl-2-oxo-tetrahydropyran-4-yl(meth)acrylate, 4-propyl-2-oxo-tetrahydropyran-4-yl(meth)acrylate, 5-oxo-tetrahydrofuran-3-yl(meth)acrylate, 2,2-dimethyl-5-oxo-tetrahydrofuran-3-yl(meth)acrylate, 4,4-dimethyl-5-oxo-tetrahydrofuran-3-yl(meth)acrylate, 2-oxo-tetrahydrofuran-3-yl(meth)acrylate, 4,4-dimethyl-2-oxo-tetrahydrofuran-3-yl(meth)acrylate, 5,5-dimethyl-2-oxo-tetrahydrofuran-3-yl(meth)acrylate, 2-oxo-tetrahydrofuran-3-yl(meth)acrylate, methyl 5-oxo-tetrahydrofuran-2-yl(meth)acrylate, 3,3-dimethyl-5-oxo-tetrahydrofuran-2-ylmethyl(meth)acrylate, 4,4-dimethyl-5-oxo-tetrahydrofuran-2-ylmethyl(meth)acrylate, and the like.

The resin (A1) may include only one type of repeating unit (a3), or may include two or more types of repeating unit (a3).

The content of the repeating unit (a3) is preferably 5 to 85 mol %, more preferably 10 to 70 mol %, and still more preferably 15 to 60 mol %, based on the total amount (100 mol %) of the repeating units included in the resin (A1). If the content of the repeating unit (a3) is less than 5 mol %, developability and exposure latitude may deteriorate. If the content of the repeating unit (a3) is more than 85 mol %, the solubility of the resin (A1) in a solvent and the resolution may decrease.

The resin (A1) may further include a repeating unit that includes an alicyclic compound, a repeating unit derived from an aromatic compound, or the like in addition to, or instead of, the repeating units (a2) and (a3).

Examples of the repeating unit that includes an alicyclic compound (hereinafter referred to as “repeating unit (a4)”) include a repeating unit derived from a monomer shown by the following general formula (3), and the like.

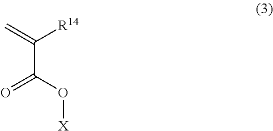

wherein R¹⁴ represents a hydrogen atom, a methyl group, or a trifluoromethyl group, and X represents an alicyclic hydrocarbon group having 4 to 20 carbon atoms.

Examples of the alicyclic hydrocarbon group having 4 to 20 carbon atoms represented by X in the general formula (3) include hydrocarbon groups including an alicyclic ring derived from a cycloalkane such as cyclobutane, cyclopentane, cyclohexane, bicyclo[2.2.1]heptane, bicyclo[2.2.2]octane, tricyclo[5.2.1.0^{2,6}]decane, tetracyclo[6.2.1.1^{3,6}.0^{2,7}]dodecane, or tricyclo[3.3.1.1^{3,7}]decane.

The alicyclic ring derived from a cycloalkane may be substituted with at least one linear, branched, or cyclic alkyl group having 1 to 4 carbon atoms, such as a methyl group, an ethyl group, an n-propyl group, an i-propyl group, an n-butyl group, a 2-methylpropyl group, a 1-methylpropyl group, or a t-butyl group, for example. The alicyclic ring derived from a cycloalkane may also be substituted with a hydroxyl group, a cyano group, a hydroxyalkyl group having 1 to 10 carbon atoms, a carboxyl group, or an oxygen atom.

Examples of a preferable monomer that produces the repeating unit (a4) include bicyclo[2.2.1]hept-2-yl(meth)acrylate, bicyclo[2.2.2]oct-2-yl(meth)acrylate, tricyclo[5.2.1.0^{2,6}]dec-7-yl(meth)acrylate, tetracyclo[6.2.1.1^{3,6}.0^{2,7}]dodec-9-yl(meth)acrylate, tricyclo[3.3.1.1^{3,7}]dec-1-yl(meth)acrylate, tricyclo[3.3.1.1^{3,7}]dec-2-yl(meth)acrylate, and the like.

The resin (A1) may include only one type of repeating unit (a4), or may include two or more types of repeating unit (a4).

The content of the repeating unit (a4) is preferably 30 mol % or less, and more preferably 25 mol % or less, based on the total amount (100 mol %) of the repeating units included in the resin (A1). If the content of the repeating unit (a4) is more than 30 mol %, the shape of the resulting resist pattern may deteriorate, or the resolution may decrease.

Examples of a preferable monomer that produces the repeating unit derived from an aromatic compound (hereinafter referred to as “repeating unit (a5)”) include styrene, α-methylstyrene, 2-methylstyrene, 3-methylstyrene, 4-methylstyrene, 2-methoxystyrene, 3-methoxystyrene, 4-methoxystyrene, 4-(2-t-butoxycarbonylethyloxy)styrene, 2-hydroxystyrene, 3-hydroxystyrene, 4-hydroxystyrene, 2-hydroxy-α-methylstyrene, 3-hydroxy-α-methylstyrene, 4-hydroxy-α-methylstyrene, 2-methyl-3-hydroxystyrene, 4-methyl-3-hydroxystyrene, 5-methyl-3-hydroxystyrene, 2-methyl-4-hydroxystyrene, 3-methyl-4-hydroxystyrene, 3,4-dihydroxystyrene, 2,4,6-trihydroxystyrene, 4-t-butoxystyrene, 4-t-butoxy-α-methylstyrene, 4-(2-ethyl-2-propoxy)styrene, 4-(2-ethyl-2-propoxy)-α-methylstyrene, 4-(1-ethoxyethoxy)styrene, 4-(1-ethoxyethoxy)-α-methylstyrene, phenyl(meth)acrylate, benzyl(meth)acrylate, acenaphthylene, 5-hydroxyacenaphthylene, 1-vinylnaphthalene, 2-vinylnaphthalene, 2-hydroxy-6-vinylnaphthalene, 1-naphthyl(meth)acrylate, 2-naphthyl(meth)acrylate, 1-naphthylmethyl(meth)acrylate, 1-anthryl(meth)acrylate, 2-anthryl(meth)acrylate, 9-anthryl(meth)acrylate, 9-anthrylmethyl(meth)acrylate, 1-vinylpyrene, and the like.

The resin (A1) may include only one type of repeating unit (a5), or may include two or more types of repeating unit (a5).

The content of the repeating unit (a5) is preferably 40 mol % or less, and more preferably 30 mol % or less, based on the total amount (100 mol %) of the repeating units included in the resin (A1). If the content of the repeating unit (a5) is more than 40 mol %, the radiation transmittance may decrease, and the pattern profile may deteriorate.

The resin (A1) may further include a repeating unit (hereinafter referred to as “additional repeating unit”) other than the repeating units (a2) to (a5).

Examples of the additional repeating unit include units obtained by cleavage of a polymerizable unsaturated bond of a polyfunctional monomer such as (meth)acrylates having a bridged hydrocarbon skeleton such as dicyclopentenyl(meth)acrylate and methyl adamantyl(meth)acrylate; carboxyl group-containing esters having a bridged hydrocarbon skeleton of an unsaturated carboxylic acid such as carboxynorbornyl(meth)acrylate, carboxytricyclodecanyl(meth)acrylate, and carboxytetracycloundecanyl(meth)acrylate;

(meth)acrylates that do not have a bridged hydrocarbon skeleton such as methyl(meth)acrylate, ethyl(meth)acrylate, n-propyl(meth)acrylate, n-butyl(meth)acrylate, 2-methylpropyl(meth)acrylate, 1-methylpropyl(meth)acrylate, t-butyl(meth)acrylate, 2-hydroxyethyl(meth)acrylate, 2-hydroxypropyl(meth)acrylate, 3-hydroxypropyl(meth)acrylate, cyclopropyl(meth)acrylate, cyclopentyl(meth)acrylate, cyclohexyl(meth)acrylate, 4-methoxycyclohexyl(meth)acrylate, 2-cyclopentyloxycarbonylethyl(meth)acrylate, 2-cyclohexyloxycarbonylethyl(meth)acrylate, and 2-(4-methoxycyclohexyl)oxycarbonylethyl(meth)acrylate;

(α-hydroxymethyl)acrylates such as methyl(α-hydroxymethyl)acrylate, ethyl(α-hydroxymethyl)acrylate, n-propyl(α-hydroxymethyl)acrylate, and n-butyl-(α-hydroxymethyl)acrylate; unsaturated nitrile compounds such as (meta)acrylonitrile, α-chloroacrylonitrile, crotonitrile, maleinitrile, fumarnitrile, mesaconitrile, citraconitrile, and itaconitrile; unsaturated amide compounds such as (meth)acrylamide, N,N-dimethyl(meth)acrylamide, crotonamide, maleinamide, fumaramide, mesaconamide, citraconamide, and itaconamide; other nitrogen-containing vinyl compounds such as N-(meth)acryloylmorpholine, N-vinyl-epsilon-caprolactam, N-vinylpyrrolidone, vinylpyridine, and vinylimidazole; unsaturated carboxylic acids (anhydrides) such as (meth)acrylic acid, crotonic acid, maleic acid, maleic anhydride, fumaric acid, itaconic acid, itaconic anhydride, citraconic acid, citraconic anhydride, and mesaconic acid; carboxyl group-containing esters that do not have a bridged hydrocarbon skeleton of unsaturated carboxylic acid such as 2-carboxyethyl(meth)acrylate, 2-carboxypropyl(meth)acrylate, 3-carboxypropyl(meth)acrylate, 4-carboxybutyl(meth)acrylate, and 4-carboxycyclohexyl(meth)acrylate;

polyfunctional monomers having a bridged hydrocarbon skeleton such as 1,2-adamantanediol di(meth)acrylate, 1,3-adamantanediol di(meth)acrylate, 1,4-adamantanediol di(meth)acrylate, and tricyclodecanyl dimethylol di(meth)acrylate; and

polyfunctional monomers that do not have a bridged hydrocarbon skeleton such as methylene glycol di(meth)acrylate, ethylene glycol di(meth)acrylate, propylene glycol di(meth)acrylate, 1,6-hexanediol di(meth)acrylate, 2,5-dimethyl-2,5-hexanediol di(meth)acrylate, 1,8-octanediol di(meth)acrylate, 1,9-nonanediol di(meth)acrylate, 1,4-bis(2-hydroxypropyl)benzene di(meth)acrylate, and 1,3-bis(2-hydroxypropyl)benzene di(meth)acrylate.

Among these, a unit obtained by cleavage of a polymerizable unsaturated bond of a (meth)acrylate having a bridged hydrocarbon skeleton, and the like are preferable.

The resin (A1) may include only one type of additional repeating unit, or may include two or more types of additional repeating unit.

The content of the additional repeating unit is preferably 50 mol % or less, and more preferably 40 mol % or less, based on the total amount (100 mol %) of the repeating units included in the resin (A1).

The resin (A1) may be produced by polymerizing polymerizable unsaturated monomers corresponding to the respective repeating units in an appropriate solvent optionally in the presence of a chain transfer agent using a radical initiator (e.g., hydroperoxide, dialkyl peroxide, diacyl peroxide, or azo compound), for example.

Examples of the solvent used for polymerization include alkanes such as n-pentane, n-hexane, n-heptane, n-octane, n-nonane, and n-decane; cycloalkanes such as cyclohexane, cycloheptane, cyclooctane, decalin, and norbornane; aromatic hydrocarbons such as benzene, toluene, xylene, ethylbenzene, and cumene; halogenated hydrocarbons such as chlorobutanes, bromohexanes, dichloroethanes, hexamethylene dibromide, and chlorobenzene; saturated carboxylic acid esters such as ethyl acetate, n-butyl acetate, i-butyl acetate, and methyl propionate; ketones such as acetone, 2-butanone, 4-methyl-2-pentanone, and 2-heptanone; ethers such as tetrahydrofuran, dimethoxyethanes, and diethoxyethanes; and the like. These solvents may be used either individually or in combination.

The reaction temperature is normally 40 to 150° C., and preferably 50 to 120° C. The reaction time is normally 1 to 48 hours, and preferably 1 to 24 hours.

The polystyrene-reduced weight average molecular weight (Mw) of the resin (A1) determined by gel permeation chromatography (GPC) is not particularly limited, but is preferably 1000 to 100,000, more preferably 1000 to 30,000, and still more preferably 1000 to 20,000. If the Mw of the resin (A1) is 1000 or less, the heat resistance of the resulting resist may decrease. If the Mw of the resin (A1) is more than 100,000, the developability of the resulting resist may decrease.

The ratio (Mw/Mn) of the Mw to the polystyrene-reduced weight average molecular weight (Mn) of the resin (A1) is normally 1 to 5, and preferably 1 to 3.

The content (solid content) of low-molecular-weight components derived from the monomers used to produce the resin (A1) is preferably 0.1 mass % or less, more preferably 0.07 mass % or less, and still more preferably 0.05 mass % or less, based on 100 mass % of the resin (A1). If the content of low-molecular-weight components is 0.1 mass % or less, the amount of eluate produced upon contact with an immersion liquid (e.g., water) during liquid immersion lithography can be reduced. Moreover, it is possible to prevent production of foreign substance during storage of the resist, prevent uneven resist application, and sufficiently suppress occurrence defects when forming a resist pattern.

Examples of low-molecular-weight components derived from the monomers include a monomer, a dimer, a trimer, and an oligomer having an Mw of 500 or less. Such components may be removed by the following purification method, for example. The amount of low-molecular-weight components may be analyzed by high-performance liquid chromatography (HPLC).

It is preferable that the resin (A1) have an impurity (e.g., halogen or metal) content as low as possible. This further improves the sensitivity, the resolution, the process stability, the pattern shape, and the like of the resulting resist.

The resin (A1) may be purified by a chemical purification method (e.g., washing with water or liquid-liquid extraction), or a combination of the chemical purification method and a physical purification method (e.g., ultrafiltration or centrifugation), for example.

The resin (A1) may be used either individually or in combination.

The radiation-sensitive resin composition according to one embodiment of the invention may include a resin (A2) as the resin component (A) in addition to the resin (A1).

Examples of the resin (A2) include (1) a resin that includes the repeating unit (a2) and the repeating unit (a3), (2) a resin that includes the repeating unit (a2), the repeating unit (a3), and at least one of the repeating unit (a4), the repeating unit (a5), and the additional repeating unit, and the like.

The resin (A2) may be used either individually or in combination.

The content of the resin (A1) in the radiation-sensitive resin composition is more than 50 mass % (i.e., the content of the resin (A1) may be 100 mass %) based on the total amount (=100 mass %) of the resin component (A) included in the radiation-sensitive resin composition. Specifically, the content of the resin (A2) is 0 to 50 mass %. The content of the resin (A1) is preferably 100 mass % or less, and more preferably 55 to 100 mass %.

When the content of the resin (A1) is more than 50 mass %, swelling during development can be suppressed due to the repeating unit (a1), and pattern collapse can be advantageously suppressed. Since the resin (A1) has moderate water repellency due to the repeating unit (a1), the resin (A1) can be used for liquid immersion lithography without using a protective film. If the content of the resin (A1) is less than 50 mass %, the above effects may not be obtained.

### <Photoacid Generator (B)>

The photoacid generator (B) (hereinafter may be referred to as “acid generator (B)”) produces an acid upon exposure. The acid-dissociable group of the repeating unit (a1) or (a2) included in the resin component dissociates (i.e., the protecting group is eliminated) due to the acid produced by the photoacid generator (B), so that the exposed area of the resist film becomes readily soluble in an alkaline developer to obtain a positive-tone resist pattern.

The acid generator (B) preferably includes a compound shown by the following general formula (4) (hereinafter referred to as “acid generator 1”).

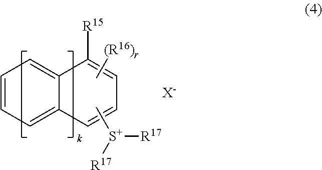

wherein k is an integer from 0 to 2.

R¹⁵ represents a hydrogen atom, a fluorine atom, a hydroxyl group, a linear or branched alkyl group having 1 to 10 carbon atoms, a linear or branched alkoxy group having 1 to 10 carbon atoms, or a linear or branched alkoxycarbonyl group having 2 to 11 carbon atoms.

R¹⁶ represents a linear or branched alkyl group having 1 to 10 carbon atoms, a linear or branched alkoxy group having 1 to 10 carbon atoms, or a linear, branched, or cyclic alkanesulfonyl group having 1 to 10 carbon atoms. r is an integer from 0 to 10.

R¹⁷ individually represent a linear or branched alkyl group having 1 to 10 carbon atoms, a substituted or unsubstituted phenyl group, or a substituted or unsubstituted naphthyl group, or bond to form a divalent group having 2 to 10 carbon atoms. Note that the divalent group may be substituted.

X⁻ represents an anion shown by R¹⁸CₙF₂ₙSO₃⁻ or R¹⁸SO₃⁻ (wherein R¹⁸ represents a fluorine atom or a substituted or unsubstituted hydrocarbon group having 1 to 12 carbon atoms, and n is an integer from 1 to 10), or an anion shown by the following general formula (5-1) or (5-2).

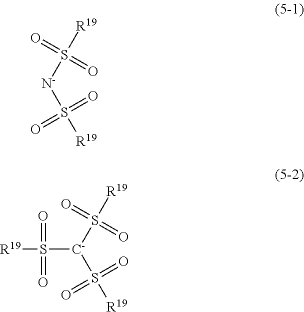

wherein R¹⁹ individually represent a linear or branched fluorine-containing alkyl group having 1 to 10 carbon atoms, or two R¹⁹ bond to form a fluorine-containing divalent organic group having 2 to 10 carbon atoms. Note that the divalent organic group may be substituted.

Examples of the linear or the branched alkyl group having 1 to 10 carbon atoms represented by R¹⁵, R¹⁶, and R¹⁷ in the general formula (4) include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group, and the like. Among these, a methyl group, an ethyl group, an n-butyl group, a t-butyl group, and the like are preferable.

Examples of the linear or branched alkoxy group having 1 to 10 carbon atoms represented by R¹⁵ and R¹⁶ include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, and the like. Among these, a methoxy group, an ethoxy group, an n-propoxy group, a n-butoxy group, and the like are preferable.

Examples of the linear or branched alkoxycarbonyl group having 2 to 11 carbon atoms represented by R¹⁵ include a methoxycarbonyl group, an ethoxycarbonyl group, an n-propoxycarbonyl group, an i-propoxycarbonyl group, an n-butoxycarbonyl group, a 2-methylpropoxycarbonyl group, an 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, an n-decyloxycarbonyl group, and the like. Among these, a methoxycarbonyl group, an ethoxycarbonyl group, an n-butoxycarbonyl group, and the like are preferable.

Examples of the linear, branched, or cyclic alkanesulfonyl group having 1 to 10 carbon atoms represented by R¹⁶ include a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, a cyclohexanesulfonyl group, and the like. Among these, a methanesylfonyl group, an ethanesulfonyl group, an n-propanesulfonyl group, an n-butanesulfonyl group, a cyclopentansulfonyl group, a cyclohexanesulfonyl group, and the like are preferable.

r in the general formula (4) is an integer from 0 to 10, and preferably an integer from 0 to 2.

Examples of the substituted or unsubstituted phenyl group represented by R¹⁷ in the general formula (4) include a phenyl group; phenyl groups substituted with a linear, branched, or cyclic alkyl group having 1 to 10 carbon atoms, such as an o-tolyl group, an m-tolyl group, a p-tolyl group, a 2,3-dimethylphenyl group, a 2,4-dimethylphenyl group, a 2,5-dimethylphenyl group, a 2,6-dimethylphenyl group, a 3,4-dimethylphenyl group, a 3,5-dimethylphenyl group, a 2,4,6-trimethylphenyl group, a 4-ethylphenyl group, a 4-t-butylphenyl group, 4-cyclohexylphenyl group, and a 4-fluorophenyl group; and groups obtained by substituting a phenyl group or the alkyl-substituted phenyl group with at least one group selected from a hydroxyl group, a carboxyl group, a cyano group, a nitro group, an alkoxyl group, an alkoxyalkyl group, an alkoxycarbonyl group, an alkoxycarbonyloxy group, and the like.

Examples of the alkoxy group as the substituent for a phenyl group or the alkyl-substituted phenyl group include linear, branched, or cyclic alkoxy groups having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, and a cyclohexyloxy group, and the like.

Examples of the alkoxyalkyl group include linear, branched, or cyclic alkoxyalkyl groups having 2 to 21 carbon atoms, such as a methoxymethyl group, an ethoxymethyl group, a 1-methoxyethyl group, a 2-methoxyethyl group, a 1-ethoxyethyl group, and a 2-ethoxyethyl group, and the like.

Examples of the alkoxycarbonyl group include linear, branched, or cyclic alkoxycarbonyl groups having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, and a cyclohexyloxycarbonyl group, and the like.

Examples of the alkoxycarbonyloxy group include linear, branched, or cyclic alkoxycarbonyloxy groups having 2 to 21 carbon atoms such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyl group, and a cyclohexyloxycarbonyl group, and the like.

The substituted or unsubstituted phenyl group represented by R¹⁶ in the general formula (4) is preferably a phenyl group, a 4-cyclohexylphenyl group, a 4-t-butylphenyl group, a 4-methoxyphenyl group, a 4-t-butoxyphenyl group, or the like.

Examples of the substituted or unsubstituted naphthyl group represented by R¹⁷ include naphthyl groups substituted or unsubstituted with a linear, branched, or cyclic alkyl group having 1 to 10 carbon atoms, such as a 1-naphthyl group, a 2-methyl-1-naphthyl group, a 3-methyl-1-naphthyl group, a 4-methyl-1-naphthyl group, a 4-methyl-1-naphthyl group, a 5-methyl-1-naphthyl group, a 6-methyl-1-naphthyl group, a 7-methyl-1-naphthyl group, a 8-methyl-1-naphthyl group, a 2,3-dimethyl-1-naphthyl group, a 2,4-dimethyl-1-naphthyl group, a 2,5-dimethyl-1-naphthyl group, a 2,6-dimethyl-1-naphthyl group, a 2,7-dimethyl-1-naphthyl group, a 2,8-dimethyl-1-naphthyl group, a 3,4-dimethyl-1-naphthyl group, a 3,5-dimethyl-1-naphthyl group, a 3,6-dimethyl-1-naphthyl group, a 3,7-dimethyl-1-naphthyl group, a 3,8-dimethyl-1-naphthyl group, a 4,5-dimethyl-1-naphthyl group, a 5,8-dimethyl-1-naphthyl group, a 4-ethyl-1-naphthyl group, a 2-naphthyl group, a 1-methyl-2-naphthyl group, a 3-methyl-2-naphthyl group, and a 4-methyl-2-naphthyl group; a group obtained by substituting a naphthyl group or the alkyl-substituted naphthyl group with at least one group such as a hydroxyl group, a carboxyl group, a cyano group, a nitro group, an alkoxyl group, an alkoxyalkyl group, an alkoxycarbonyl group, or an alkoxycarbonyloxy group; and the like.

Examples of the alkoxyl group, the alkoxyalkyl group, the alkoxycarbonyl group, and the alkoxycarbonyloxy group as the substituent include the groups mentioned above in connection with a phenyl group and the alkyl-substituted phenyl group.

The substituted or unsubstituted naphthyl group represented by R¹⁷ in the general formula (4) is preferably a 1-naphthyl group, a 1-(4-methoxynaphthyl) group, a 1-(4-ethoxynaphthyl) group, a 1-(4-n-propoxynaphthyl) group, a 1-(4-n-butoxynaphthyl) group, a 2-(7-methoxynaphthyl) group, a 2-(7-ethoxynaphthyl) group, a 2-(7-n-propoxynaphthyl) group, a 2-(7-n-butoxynaphthyl) group, or the like.

The divalent group having 2 to 10 carbon atoms formed by two R¹⁷ is preferably a group that forms a five- or six-membered ring (particularly preferably a five-membered ring (i.e., tetrahydrothiophene ring)) together with the sulfur atom in the general formula (4).

Examples of a substituent for the divalent group include the groups (e.g., hydroxyl group, carboxyl group, cyano group, nitro group, alkoxyl group, alkoxyalkyl group, alkoxycarbonyl group, and alkoxycarbonyloxy group) mentioned above in connection with a phenyl group and the alkyl-substituted phenyl group.

R¹⁷ in the general formula (4) preferably represents a methyl group, an ethyl group, a phenyl group, a 4-methoxyphenyl group, or a 1-naphthyl group, or bond to form a divalent group having a tetrahydrothiophene ring structure together with the sulfur atom.

X⁻ in the general formula (4) represents an anion shown by R¹⁸CₙF₂ₙSO₃⁻ or R¹⁸SO₃⁻, or an anion shown by the general formula (5-1) or (5-2). When X⁻ represents an anion shown by R¹⁸CₙF₂ₙSO₃⁻, —CₙF₂ₙ— is a linear or branched perfluoroalkylene group having n carbon atoms. n is preferably 1, 2, 4, or 8.

The substituted or unsubstituted hydrocarbon group having 1 to 12 carbon atoms represented by R¹⁸ is preferably an alkyl group having 1 to 12 carbon atoms, a cycloalkyl group, or a bridged alicyclic hydrocarbon group.

Specific examples of the substituted or unsubstituted hydrocarbon group having 1 to 12 carbon atoms represented by R¹⁸ include a methyl group, an ethyl group, an n-propyl group, an i-propyl group, an n-butyl group, a 2-methylpropyl group, a 1-methylpropyl group, a t-butyl group, an n-pentyl group, an neopentyl group, an n-hexyl group, a cyclohexyl group, an n-heptyl group, an n-octyl group, a 2-ethylhexyl group, an n-nonyl group, an n-decyl group, a norbornyl group, a norbornylmethyl group, a hydroxynorbornyl group, an adamantyl group, and the like.

When X⁻ is an anion shown by the general formula (5-1) or (5-2), R¹⁹ individually represent a linear or branched fluorine-containing alkyl group having 1 to 10 carbon atoms, or two R¹⁹ bond to form a fluorine-containing divalent organic group having 2 to 10 carbon atoms. Note that the divalent organic group may be substituted.

Examples of the linear or branched alkyl group having 1 to 10 carbon atoms represented by R¹⁹ in the general formula (5-1) or (5-2) include a trifluoromethyl group, a pentafluoroethyl group, a heptafuluoropropyl group, a nonafluorobutyl group, a dodecafluoropentyl group, a perfluorooctyl group, and the like.

Examples of the divalent organic group having 2 to 10 carbon atoms formed by R¹⁹ include a tetrafluoroethylene group, a hexafluoropropylene group, an octafluorobutylene group, a decafluoropentylene group, an undecafluorohexylene group, and the like.

Examples of a preferable anion X⁻ in the general formula (4) include a trifluoromethanesulfonate anion, a perfluoro-n-butanesulfonate anion, a perfluoro-n-octanesulfonate anion, a 2-bicyclo[2.2.1]hept-2-yl-1,1,2,2-tetrafluoroethanesulfonate anion, a 2-bicyclo[2.2.1]hept-2-yl-1,1-difluoroethanesulfonate anion, anions shown by the following formulas (6-1) to (6-7), and the like.

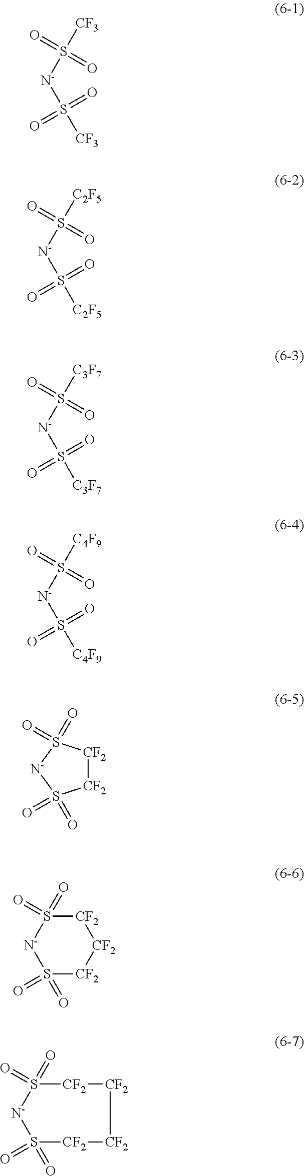

Specific examples of a preferable compound shown by the general formula (4) include triphenylsulfonium trifluoromethanesulfonate, tri-tert-butylphenylsulfonium trifluoromethanesulfonate, 4-cyclohexylphenyl-diphenylsulfonium trifluoromethanesulfonate, 4-methanesulfonylphenyl-diphenylsulfonium trifluoromethanesulfonate, 1-(3,5-dimethyl 4-hydroxyphenyl)tetrahydrothiophenium trifluoromethanesulfonate, 1-(4-n-butoxynaphthyl)tetrahydrothiophenium trifluoromethanesulfonate,

triphenylsulfonium perfluoro-n-butanesulfonate, tri-tert-butylphenylsulfonium perfluoro-n-butanesulfonate, 4-cyclohexylphenyl-diphenylsulfonium perfluoro-n-butanesulfonate, 4-methanesulfonylphenyl-diphenylsulfonium perfluoro-n-butanesulfonate, 1-(3,5-dimethyl-4-hydroxyphenyl)tetrahydrothiophenium perfluoro-n-butanesulfonate, 1-(4-n-butoxynaphthyl)tetrahydrothiophenium perfluoro-n-butanesulfonate,

triphenylsulfonium perfluoro-n-octanesulfonate, tri-tert-butylphenylsulfonium perfluoro-n-octanesulfonate, 4-cyclohexylphenyl-diphenylsulfonium perfluoro-n-octanesulfonate, 4-methanesulfonylphenyl-diphenylsulfonium perfluoro-n-octanesulfonate, 1-(3,5-dimethyl-4-hydroxyphenyl)tetrahydrothiophenium perfluoro-n-octanesulfonate, 1-(4-n-butoxynaphthyl)tetrahydrothiophenium perfluoro-n-octanesulfonate,

triphenylsulfonium 2-(bicyclo[2.2.1]hept-2′-yl)-1,1,2,2-tetrafluoroethanesulfonate, tri-tert-butylphenylsulfonium 2-(bicyclo[2.2.1]hept-2′-yl)-1,1,2,2-tetrafluoroethanesulfonate, 4-cyclohexylphenyldiphenylsulfonium 2-(bicyclo[2.2.1]hept-2′-yl)-1,1,2,2-tetrafluoroethane sulfonate, 4-methanesulfonylphenyldiphenylsulfonium 2-(bicyclo[2.2.1]hept-2′-yl)-1,1,2,2-tetrafluoroethanesulfonate, 1-(3,5-dimethyl-4-hydroxyphenyl)tetrahydrothiophenium 2-(bicyclo[2.2.1]hept-2′-yl)-1,1,2,2-tetrafluoroethanesulfonate, 1-(4-n-butoxynaphthyl)tetrahydrothiophenium 2-(bicyclo[2.2.1]hept-2′-yl)-1,1,2,2-tetrafluoroethanesulfonate,

triphenylsulfonium 2-(bicyclo[2.2.1]hept-2′-yl)-1,1-difluoroethanesulfonate, tri-tert-butylphenylsulfonium 2-(bicyclo[2.2.1]hept-2′-yl)-1,1-difluoroethanesulfonate, 4-cyclohexylphenyldiphenylsulfonium 2-(bicyclo[2.2.1]hept-2′-yl)-1,1-difluoroethanesulfonate, 4-methanesulfonylphenyldiphenylsulfonium 2-(bicyclo[2.2.1]hept-2′-yl)-1,1-difluoroethanesulfonate, 1-(3,5-dimethyl-4-hydroxyphenyl)tetrahydrothiophenium 2-(bicyclo[2.2.1]′hept-2′-yl)-1,1-difluoroethanesulfonate, 1-(4-n-butoxynaphthyl)tetrahydrothiophenium 2-(bicyclo[2.2.1]hept-2′-yl)-1,1-difluoroethanesulfonate, compounds shown by the following formulas B1 to B15, and the like.

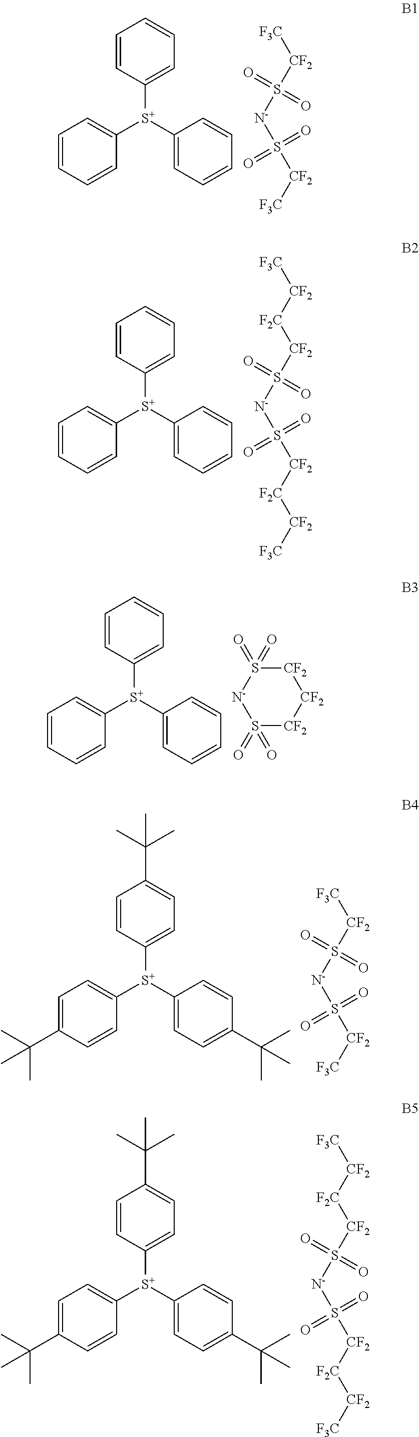

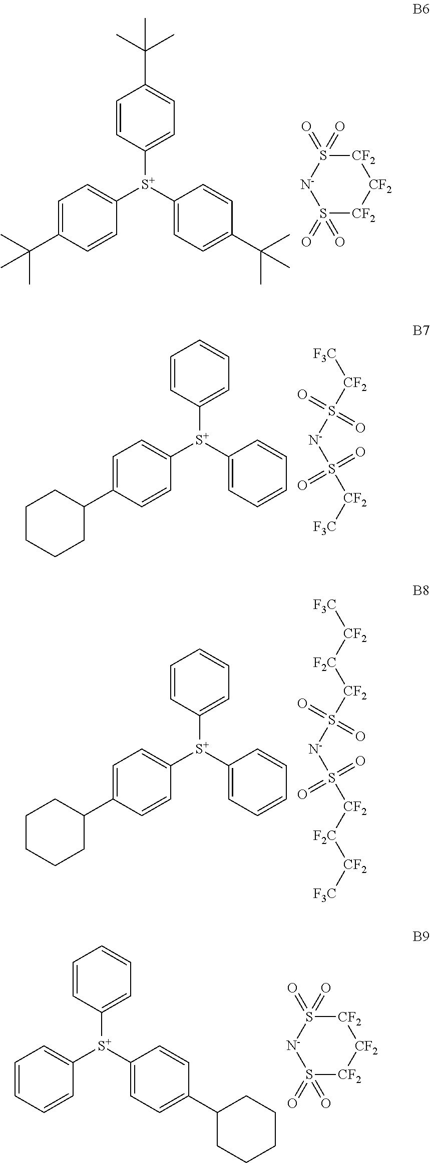

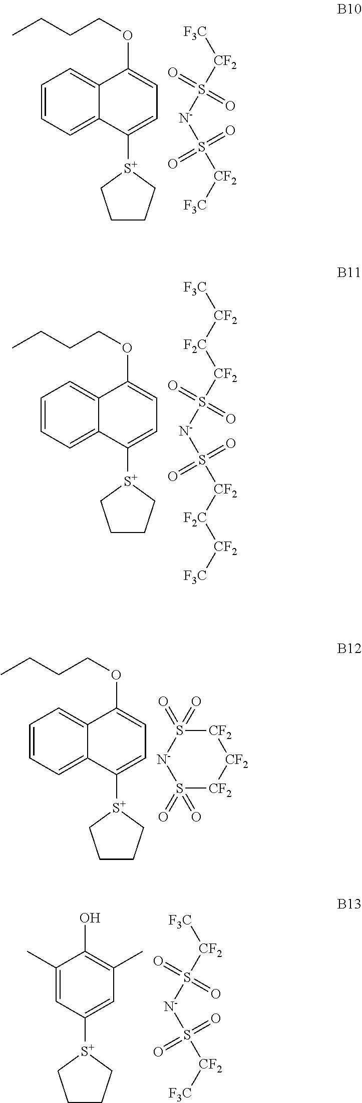

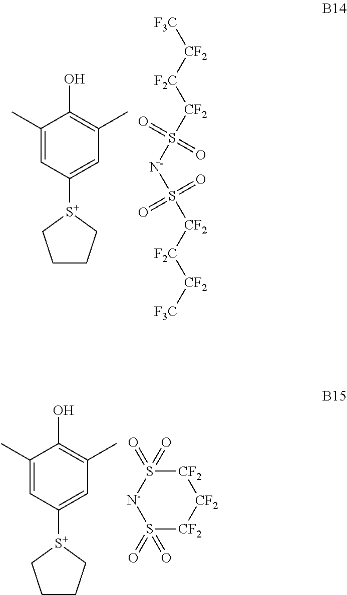

These acid generators 1 may be used either individually or in combination.

Examples of a photoacid generator (hereinafter referred to as “additional acid generator”) other than the acid generator 1 that may be used as the acid generator (B) include onium salt compounds, halogen-containing compounds, diazoketone compounds, sulfone compounds, sulfonic acid compounds, and the like. Specific examples of the additional acid generator are given below.

### (Onium Salt Compound)

Examples of the onium salt compounds include iodonium salts, sulfonium salts, phosphonium salts, diazonium salts, pyridinium salts, and the like.

Specific examples of the onium salt compounds include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, cyclohexyl•2-oxocyclohexyl•methylsulfonium trifluoromethanesulfonate, dicyclohexyl•2-oxocyclohexylsulfonium trifluoromethanesulfonate, 2-oxocyclohexyldimethylsulfonium trifluoromethanesulfonate, and the like.

### (Halogen-Containing Compound)

Examples of the halogen-containing compounds include haloalkyl group-containing hydrocarbon compounds, haloalkyl group-containing heterocyclic compounds, and the like.

Specific examples of the halogen-containing compounds include (trichloromethyl)-s-triazine derivatives such as phenylbis(trichloromethyl)-s-triazine, 4-methoxyphenylbis(trichloromethyl)-s-triazine, 1-naphthylbis(trichloromethyl)-s-triazine, 1,1-bis(4-chlorophenyl)-2,2,2-trichloroethane, and the like.

### (Diazoketone Compound)

Examples of the diazoketone compounds include 1,3-diketo-2-diazo compounds, diazobenzoquinone compounds, diazonaphthoquinone compounds, and the like.

Specific examples of the diazoketone compounds include 1,2-naphthoquinonediazido-4-sulfonyl chloride, 1,2-naphthoquinonediazido-5-sulfonyl chloride, 1,2-naphthoquinonediazido-4-sulfonate or 1,2-naphthoquinonediazido-5-sulfonate of 2,3,4,4′-tetrahydroxybenzophenone, 1,2-naphthoquinonediazido-4-sulfonate or 1,2-naphthoquinonediazido-5-sulfonate of 1,1,1-tris(4-hydroxyphenyl)ethane, and the like.

### (Sulfone Compound)

Examples of the sulfone compounds include β-ketosulfone, β-sulfonylsulfone, α-diazo compounds of these compounds, and the like.

Specific examples of the sulfone compounds include 4-trisphenacylsulfone, mesitylphenacylsulfone, bis(phenylsulfonyl)methane, and the like.

### (Sulfonic Acid Compound)

Examples of the sulfonic acid compounds include alkyl sulfonates, alkylimide sulfonates, haloalkyl sulfonates, aryl sulfonates, imino sulfonates, and the like.

Specific examples of the sulfonic acid compounds include benzointosylate, tris(trifluoromethanesulfonate) of pyrogallol, nitrobenzyl-9,10-diethoxyanthracene-2-sulfonate, trifluoromethanesulfonylbicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]hept-5-ene-2,3-dicarbodiimide, 2-bicyclo[2.2.1]hept-2-yl-1,1,2,2-tetrafluoroethanesulfonylbicyclo[2.2.1]hept-5-ene-2,3-dicar bodiimide, N-(trifluoromethanesulfonyloxy)succinimide, N-(nonafluoro-n-butanesulfonyloxy)succinimide, N-(perfluoro-n-octanesulfonyloxy)succinimide, N-(2-bicyclo[2.2.1]hept-2-yl-1,1,2,2-tetrafluoroethanesulfonyloxy)succinimide, 1,8-naphthalenedicarboxylic acid imide trifluoromethanesulfonate, 1,8-naphthalenedicarboxylic acid imide nonafluoro-n-butanesulfonate, 1,8-naphthalenedicarboxylic acid imide perfluoro-n-octanesulfonate, and the like.

Among these, diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, cyclohexyl•2-oxocyclohexyl•methylsulfonium trifluoromethanesulfonate, dicyclohexyl•2-oxocyclohexylsulfonium trifluoromethanesulfonate, 2-oxocyclohexyldimethylsulfonium trifluoromethanesulfonate,

trifluoromethanesulfonylbicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]hept-5-ene-2,3-dicarbodiimide, 2-bicyclo[2.2.1]hept-2-yl-1,1,2,2-tetrafluoroethanesulfonylbicyclo[2.2.1]hept-5-ene-2,3-dicar bodiimide, N-(trifluoromethanesulfonyloxy)succinimide, N-(nonafluoro-n-butanesulfonyloxy)succinimide, N-(perfluoro-n-octanesulfonyloxy)succinimide, N-(2-bicyclo[2.2.1]hept-2-yl-1,1,2,2-tetrafluoroethanesulfonyloxy)succinimide, 1,8-naphthalenedicarboxylic acid imide trifluoromethanesulfonate, and the like are preferable.

These additional acid generators may be used either individually or in combination.

In order to ensure that the resulting resist exhibits excellent sensitivity and developability, the acid generator 1 and the additional acid generator is normally used in a total amount of 0.1 to 20 parts by mass, and preferably 0.5 to 10 parts by mass, based on 100 parts by mass of the resin component (A). If the total amount of the acid generator 1 and the additional acid generator is less than 0.1 parts by mass, the sensitivity and the developability of the resulting resist may decrease. If the total amount of the acid generator 1 and the additional acid generator is more than 20 parts by mass, transparency to radiation may decrease, so that it may be difficult to obtain a rectangular resist pattern.

The additional acid generator is normally used in an amount of 80 mass % or less, and preferably 60 mass % or less, based on the total amount (=100 mass %) of the acid generator 1 and the additional acid generator.

### <Solvent (C)>

The radiation-sensitive resin composition according to one embodiment of the invention is normally prepared as a composition solution by dissolving the components in a solvent so that the total solid content is normally 1 to 50 mass %, and preferably 1 to 25 mass %, and filtering the solution using a filter having a pore size of about 0.2 μm, for example.

Examples of the solvent (C) include linear or branched ketones such as 2-butanone, 2-pentanone, 3-methyl-2-butanone, 2-hexanone, 4-methyl-2-pentanone, 3-methyl-2-pentanone, 3,3-dimethyl-2-butanone, 2-heptanone, 2-octanone; cyclic ketones such as cyclopentanone, 3-methylcyclopentanone, cyclohexanone, 2-methylcyclohexanone, 2,6-dimethylcyclohexanone, and isophorone; propylene glycol monoalkyl ether acetates such as propylene glycol monomethyl ether acetate, propylene glycol monoethyl ether acetate, propylene glycol mono-n-propyl ether acetate, propylene glycol mono-i-propyl ether acetate, propylene glycol mono-n-butyl ether acetate, propylene glycol mono-i-butyl ether acetate, propylene glycol mono-sec-butyl ether acetate, and propylene glycol mono-t-butyl ether acetate; alkyl 2-hydroxypropionates such as methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and t-butyl 2-hydroxypropionate; alkyl 3-alkoxypropionates such as methyl 3-methoxypropionate, ethyl 3-methoxypropionate, methyl 3-ethoxypropionate, and ethyl 3-ethoxypropionate;

n-propyl alcohol, i-propyl alcohol, n-butyl alcohol, t-butyl alcohol, cyclohexanol, ethylene glycol monomethyl ether, ethylene glycol monoethyl ether, ethylene glycol mono-n-propyl ether, ethylene glycol mono-n-butyl ether, diethylene glycol dimethyl ether, diethylene glycol diethyl ether, diethylene glycol di-n-propyl ether, diethylene glycol di-n-butyl ether, ethylene glycol monomethyl ether acetate, ethylene glycol monoethyl ether acetate, ethylene glycol mono-n-propyl ether acetate, propylene glycol monomethyl ether, propylene glycol monoethyl ether, propylene glycol mono-n-propyl ether, toluene, xylene, ethyl 2-hydroxy-2-methyl propionate, ethoxyethyl acetate, ethyl hydroxyacetate, methyl 2-hydroxy-3-methylbutyrate, 3-methoxybutylacetate, 3-methyl-3-methoxybutylacetate, 3-methyl-3-methoxybutylpropionate, 3-methyl-3-methoxybutylbutyrate, ethyl acetate, n-propyl acetate, n-butyl acetate, methyl acetoacetate, ethyl acetoacetate, methyl pyruvate, ethyl pyruvate, N-methyl pyrrolidone, N,N-dimethylformamide, N,N-dimethylacetamide, benzyl ethyl ether, di-n-hexyl ether, diethylene glycol monomethyl ether, diethylene glycol monoethyl ether, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, and the like.

Among these, linear or branched ketones, cyclic ketones, propylene glycol monoalkyl ether acetates, alkyl 2-hydroxypropionates, alkyl 3-alkoxypropionates, γ-butyrolactone, and the like are preferable.

These solvents (C) may be used either individually or in combination.

### <Nitrogen-Containing Compound>

The radiation-sensitive resin composition according to one embodiment of the invention may include a nitrogen-containing compound in addition to the resin component (A), the acid generator (B), and the solvent (C).

The nitrogen-containing compound is a component (acid diffusion controller) that controls diffusion of an acid generated by the acid generator upon exposure in the resist film to suppress undesired chemical reactions in the unexposed area. The acid diffusion controller improves the storage stability of the resulting radiation-sensitive resin composition. Moreover, the acid diffusion controller further improves the resolution of the resulting resist, and suppresses a change in line width of the resist pattern due to a variation in post-exposure delay (PED). Specifically, a composition that exhibits excellent process stability can be obtained.

Examples of the nitrogen-containing compound include tertiary amine compounds, other amine compounds, amide group-containing compounds, urea compounds, nitrogen-containing heterocyclic compounds, and the like.

Examples of preferable tertiary amine compounds include mono(cyclo)alkylamines such as n-hexylamine, n-heptylamine, n-octylamine, n-nonylamine, n-decylamine, and cyclohexylamine; di(cyclo)alkylamines such as di-n-butylamine, di-n-pentylamine, di-n-hexylamine, di-n-heptylamine, di-n-octylamine, di-n-nonylamine, di-n-decylamine, cyclohexylmethylamine, and dicyclohexylamine; tri(cyclo)alkylamines such as triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, cyclohexyldimethylamine, methyldicyclohexylamine, and tricyclohexylamine; substituted alkylamines such as 2,2′,2″-nitrotriethanol; aniline, N-methylaniline, N,N-dimethylaniline, 2-methylaniline, 3-methylaniline, 4-methylaniline, 4-nitroaniline, diphenylamine, triphenylamine, naphthylamine, 2,4,6-tri-tert-butyl-N-methylaniline, N-phenyldiethanolamine, 2,6-diisopropylaniline, and the like.

Examples of preferable other amine compounds include ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2′-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, bis(2-diethylaminoethyl)ether, 1-(2-hydroxyethyl)-2-imidazolizinone, 2-quinoxalinol, N,N,N′,N′-tetrakis(2-hydroxypropyl)ethylenediamine, N,N,N′,N″,N″-pentamethyldiethylenetriamine, and the like.

Examples of preferable amide group-containing compounds include N-t-butoxycarbonyl group-containing amino compounds such as N-t-butoxycarbonyl di-n-octylamine, N-t-butoxycarbonyl di-n-nonylamine, N-t-butoxycarbonyl di-n-decylamine, N-t-butoxycarbonyl dicyclohexylamine, N-t-butoxycarbonyl-1-adamantylamine, N-t-butoxycarbonyl-2-adamantylamine, N-t-butoxycarbonyl-N-methyl-1-adamantylamine, (S)-(−)-1-(t-butoxycarbonyl)-2-pyrrolidine methanol, (R)-(+)-1-(t-butoxycarbonyl)-2-pyrrolidine methanol, N-t-butoxycarbonyl-4-hydroxypiperidine, N-t-butoxycarbonylpyrrolidine, N-t-butoxycarbonylpiperazine, N-t-butoxycarbonylpiperidine, N,N-di-t-butoxycarbonyl-1-adamantylamine, N,N-di-t-butoxycarbonyl-N-methyl-1-adamantylamine, N-t-butoxycarbonyl-4,4′-diaminodiphenylmethane, N,N′-di-t-butoxycarbonylhexamethylenediamine, N,N,N′N′-tetra-t-butoxycarbonylhexamethylenediamine, N,N′-di-t-butoxycarbonyl-1,7-diaminoheptane, N,N′-di-t-butoxycarbonyl-1,8-diaminonooctane, N,N′-di-t-butoxycarbonyl-1,9-diaminononane, N,N′-di-t-butoxycarbonyl-1,10-diaminodecane, N,N′-di-t-butoxycarbonyl-1,12-diaminododecane, N,N′-di-t-butoxycarbonyl-4,4′-diaminodiphenylmethane, N-t-butoxycarbonylbenzimidazole, N-t-butoxycarbonyl-2-methylbenzimidazole, and N-t-butoxycarbonyl-2-phenylbenzimidazole; formamide, N-methylformamide, N,N-dimethylformamide, acetamide, N-methylacetamide, N,N-dimethylacetamide, propionamide, benzamide, pyrrolidone, N-methylpyrrolidone, N-acetyl-1-adamantylamine, tris(2-hydroxyethyl)isocyanuric acid, and the like.

Examples of preferable urea compounds include urea, methylurea, 1,1-dimethylurea, 1,3-dimethylurea, 1,1,3,3-tetramethylurea, 1,3-diphenylurea, tri-n-butylthiourea, and the like.

Examples of preferable other nitrogen-containing heterocyclic compounds include imidazoles such as imidazole, 4-methylimidazole, 4-methyl-2-phenylimidazole, benzimidazole, 2-phenylbenzimidazole, 1-benzyl-2-methylimidazole, and 1-benzyl-2-methyl-1H-imidazole; pyridines such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinamide, quinoline, 4-hydroxyquinoline, 8-oxyquinoline, acridine, and 2,2′:6′,2″-terpyridine; piperazines such as piperazine and 1-(2-hydroxyethyl)piperazine; pyrazine, pyrazole, pyridazine, quinoxaline, purine, pyrrolidine, piperidine, piperidineethanol, 3-piperidino-1,2-propanediol, morpholine, 4-methylmorpholine, 1-(4-morpholinyl)ethanol, 4-acetylmorpholine, 3-(N-morpholino)-1,2-propanediol, 1,4-dimethylpiperazine, 1,4-diazabicyclo[2.2.2]octane, and the like.

These nitrogen-containing compounds may be used either individually or in combination.

The acid diffusion controller (nitrogen-containing compound) is normally used in an amount of 15 parts by mass or less, preferably 10 parts by mass or less, and still more preferably 5 parts by mass or less, based on 100 parts by mass of the resin component (A). If the amount of the acid diffusion controller is more than 15 parts by mass, the sensitivity of the resulting resist may decrease. If the amount of the acid diffusion controller is less than 0.001 parts by mass, the pattern shape or the dimensional accuracy of the resulting resist may decrease depending on the processing conditions.

### <Additive>

The radiation-sensitive resin composition according to one embodiment of the invention may optionally include additives such as an alicyclic additive, a surfactant, and a sensitizer.

The alicyclic additive further improves the dry etching resistance, the pattern shape, adhesion to a substrate, and the like.

Examples of the alicyclic additive include adamantane derivatives such as 1-adamantanecarboxylic acid, 2-adamantanone, t-butyl-1-adamantanecarboxylate, t-butoxycarbonylmethyl 1-adamantanecarboxylate, α-butyrolactone 1-adamantanecarboxylate, di-t-butyl 1,3-adamantanedicarboxylate, t-butyl 1-adamantaneacetate, t-butoxycarbonylmethyl 1-adamantaneacetate, di-t-butyl 1,3-adamantanediacetate, and 2,5-dimethyl-2,5-di(adamantylcarbonyloxy)hexane; deoxycholates such as t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, and mevalonolactone deoxycholate; lithocholates such as t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate; alkyl carboxylates such as dimethyl adipate, diethyl adipate, dipropyl adipate, di-n-butyl adipate, and di-t-butyl adipate; 3-[2-hydroxy-2,2-bis(trifluoromethyl)ethyl]tetracyclo[4.4.0.1^{2,5}.1^{7,10}]dodecane; and the like, These alicyclic additives may be used either individually or in combination.

The surfactant improves applicability, striation, developability, and the like.

Examples of the surfactant include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate, commercially available products such as KP341 (manufactured by Shin-Etsu Chemical Co., Ltd.), Polyflow No. 75, Polyflow No. 95 (manufactured by Kyoeisha Chemical Co., Ltd.), EFTOP EF301, EFTOP EF303, EFTOP EF352 (manufactured by JEMCO, Inc.), Megafac F171, Megafac F173 (manufactured by DIC Corporation), Fluorad FC430, Fluorad FC431 (manufactured by Sumitomo 3M Ltd.), Asahi Guard AG710, Surflon S-382, Surflon SC-101, Surflon SC-102, Surflon SC-103, Surflon SC-104, Surflon SC-105, Surflon SC-106 (manufactured by Asahi Glass Co., Ltd.), and the like. These surfactants may be used either individually or in combination.

The sensitizer absorbs the energy of radiation, and transmits the energy to the acid generator (B), so that the amount of acid generated by the acid generator (B) increases. The sensitizer improves the apparent sensitivity of the radiation-sensitive resin composition.

Examples of the sensitizer include carbazoles, acetophenones, benzophenones, naphthalenes, phenols, biacetyl, eosine, rose bengal, pyrenes, anthracenes, phenothiazines, and the like. These sensitizers may be used either individually or in combination.

A dye or a pigment visualizes the latent image of the exposed area to reduce the effects of halation during exposure. An adhesion improver improves adhesion to a substrate.

Examples of other additives include an alkali-soluble resin, a low-molecular-weight alkali-solubility controller that includes an acid-dissociable protecting group, a halation inhibitor, a preservation stabilizer, an antifoaming agent, and the like.

### <Receding Contact Angle>

A photoresist film formed by applying the radiation-sensitive resin composition according to one embodiment of the invention to a substrate preferably has a receding contact angle with water of 68° or more, and more preferably 70° or more. If the receding contact angle is less than 68°, water may remain during high-speed scan exposure, so that watermark defects may occur.

Note that the term “receding contact angle” used herein refers to a contact angle formed by a liquid surface and a substrate when dripping 25 μl of water onto a substrate on which a photoresist film is formed of the resin composition according to one embodiment of the invention, and sucking water droplets on the substrate at a rate of 10 μl/min. The receding contact angle may be measured using an instrument “DSA-10” (manufactured by KRUS) (see examples).

### [2] Polymer

A polymer according to one embodiment of the invention includes a repeating unit shown by the general formula (1), and a repeating unit that includes a lactone skeleton.

The polymer may suitably be used as the resin component of the above radiation-sensitive resin composition for liquid immersion lithography.

The description given above in the section entitled “Resin (A1)” in connection with the repeating unit shown by the general formula (1) and the repeating unit that includes a lactone skeleton (repeating unit (a3)) is applied to the repeating unit shown by the general formula (1) and the repeating unit that includes a lactone skeleton.

The polymer may include the repeating unit (a2), the repeating unit that includes an alicyclic compound, and the repeating unit derived from an aromatic compound mentioned above in connection with the resin (A1), and the like.

### [3] Resist Pattern-Forming Method

The radiation-sensitive resin composition according to one embodiment of the invention is useful as a chemically-amplified resist. When using the radiation-sensitive resin composition as a chemically-amplified resist, the acid-dissociable group included in the resin component (mainly the resin (A1)) dissociates due to an acid generated by the acid generator upon exposure so that a carboxyl group is produced. As a result, the solublity of the exposed area of the resist in an alkaline developer increases. Therefore, the exposed area is dissolved (removed) in an alkaline developer to obtain a positive-tone resist pattern.

A resist pattern may be formed by a method that includes forming a photoresist film on a substrate using the radiation-sensitive resin composition (hereinafter may be referred to as “step (1)”), subjecting the photoresist film to liquid immersion lithography (hereinafter may be referred to as “step (2)”), and developing the photoresist film subjected to liquid immersion lithography to form a resist pattern (hereinafter may be referred to as “step (3)”).

In the step (1), a photoresist film is formed by applying a resin composition solution produced using the radiation-sensitive composition according to one embodiment of the invention to a substrate (e.g., silicon wafer or aluminum-coated wafer) by an appropriate application method (e.g., rotational coating, cast coating, or roll coating). Specifically, the radiation-sensitive resin composition solution is applied so that the resulting resist film has a given thickness, and prebaked (PB) to volatilize the solvent from the film to obtain a resist film.

The thickness of the resist film is not particularly limited, but is preferably 10 to 5000 nm, and more preferably 10 to 2000 nm.

The prebaking temperature is determined depending on the composition of the radiation-sensitive resin composition, but is preferably about 30 to 200° C., and more preferably 50 to 150° C.

In the step (2), radiation is applied to the photoresist film obtained by the step (1) via an immersion medium (e.g., water) (i.e., liquid immersion lithography). Note that radiation is normally applied to the photoresist film via a mask having a given pattern.

As radiation used for exposure, visible rays, ultraviolet rays, deep ultraviolet rays, X-rays, electron beams, or the like are appropriately selected depending on the type of acid generator. It is preferable to use deep ultraviolet rays such as ArF excimer laser light (wavelength: 193 nm) or KrF excimer laser light (wavelength: 248 nm). It is particularly preferable to use ArF excimer laser light (wavelength: 193 nm).

The exposure conditions (e.g., dose) may be appropriately determined depending on the composition of the radiation-sensitive resin composition, the type of additive, and the like.

It is preferable to perform post-exposure bake (PEB) after exposure. The acid-dissociable group included in the resin component smoothly dissociates due to PEB. The PEB temperature is appropriately adjusted depending on the composition of the radiation-sensitive resin composition, but is normally 30 to 200° C., and preferably 50 to 170° C.

In order to bring out the potential of the radiation-sensitive resin composition to a maximum extent, an organic or inorganic antireflective film may be formed on a substrate, as disclosed in Japanese Examined Patent Publication (KOKOKU) No. 6-12452 (Japanese Patent Application Publication (KOKAI) No. 59-93448), for example. A protective film may be formed on the resist film so that the resist film is not affected by basic impurities and the like contained in the environmental atmosphere, as disclosed in Japanese Patent Application Publication (KOKAI) No. 5-188598, for example. In order to prevent outflow of the acid generator and the like from the resist film during liquid immersion lithography, a liquid immersion lithography protective film may be formed on the resist film, as disclosed in Japanese Patent Application Publication (KOKAI) No. 2005-352384, for example. These technologies may be used in combination.

When using a resist pattern-forming method utilizing liquid immersion lithography, a resist pattern can be formed by the resist film obtained using the radiation-sensitive resin composition according to one embodiment of the invention without providing a protective film (upperlayer film) on the resist film. In this case, since it is unnecessary to form a protective film (upperlayer film), the throughput is improved.

In the step (3), the resist film subjected to liquid immersion lithography is developed to form a given resist pattern.

As the developer, it is preferable to use an alkaline aqueous solution prepared by dissolving at least one alkaline compound (e.g., sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, or 1,5-diazabicyclo-[4.3.0]-5-nonene) in water.

The concentration of the alkaline aqueous solution is normally 10 mass % or less. If the concentration of the alkaline aqueous solution is more than 10 mass %, the unexposed area may also be dissolved in the developer.

An organic solvent may be added to the alkaline aqueous solution (developer).

Examples of the organic solvent include ketones such as acetone, methyl ethyl ketone, methyl i-butyl ketone, cyclopentanone, cyclohexanone, 3-methylcyclopentanone, and 2,6-dimethylcyclohexanone; alcohols such as methanol, ethanol, n-propyl alcohol, i-propyl alcohol, n-butyl alcohol, t-butyl alcohol, cyclopentanol, cyclohexanol, 1,4-hexanediol, and 1,4-hexanedimethylol; ethers such as tetrahydrofuran and dioxane; esters such as ethyl acetate, n-butyl acetate, and i-amyl acetate; aromatic hydrocarbons such as toluene and xylene; phenol, acetonylacetone, dimethylformamide; and the like. These organic solvents may be used either individually or in combination.

The organic solvent is preferably used in an amount of 100 parts by volume or less based on 100 parts by volume of the alkaline aqueous solution. If the amount of the organic solvent is more than 100 parts by volume, the exposed area may remain undeveloped due to a decrease in developability.

An appropriate amount of surfactant or the like may also be added to the alkaline aqueous solution (developer).

After development using the alkaline aqueous solution (developer), the resist film is normally washed with water, and dried.

### EXAMPLES

The embodiment of the invention is further described below by way of examples. Note that the invention is not limited to the following examples. In the examples, the unit “parts” refers to “parts by mass” unless otherwise indicated.

The following measurement methods and evaluation methods were used in each synthesis example.

### (1) Mw and Mn

The Mw and the Mn of each resin were determined by gel permeation chromatography (GPC) (standard: monodispersed polystyrene) using GPC columns manufactured by Tosoh Corp. (G2000HXL×2, G3000HXL×1, G4000HXL×1) (flow rate: 1.0 ml/min, column temperature: 40° C., eluant: tetrahydrofuran). The dispersibility (Mw/Mn) was calculated from the measurement results.

### (2) ¹³C-NMR Analysis

Each resin was subjected to ¹³C-NMR analysis using an instrument “JNM-EX270” (manufactured by JEOL Ltd.).

(3) Amount of Low-Molecular-Weight Components Derived from Monomers

The amount of low-molecular-weight components was determined by high-performance liquid chromatography (HPLC) using an Intersil ODS-25 micrometer column (4.6 mm (diameter)×250 mm) (manufactured by GL Sciences Inc.) (flow rate: 1.0 ml/min, eluant: acrylonitrile/0.1% phosphoric acid aqueous solution).

The amount (mass %) of low-molecular-weight components refers to a value based on the total amount (=100 mass %) of the resin.

Each synthesis example is described below.

The following monomers (M-1) to (M-10) were used to synthesize the resin component (A) (resins (A-1) to (A-11)).

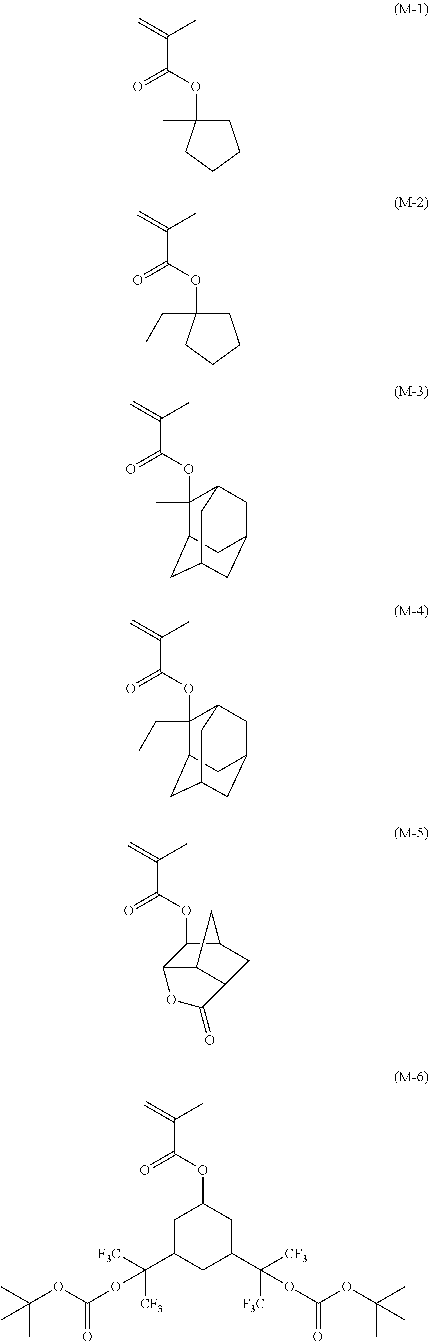

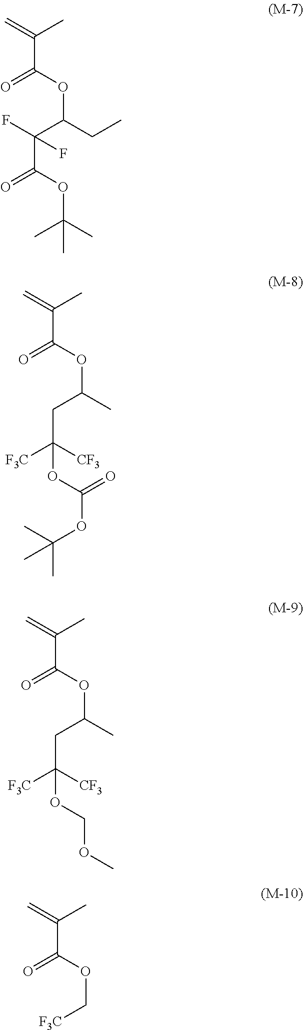

### <Synthesis of Resin (A-1)>

34.61 g (50 mol %) of the monomer (M-1), 28.82 g (10 mol %) of the monomer (M-6), and 36.57 g (40 mol %) of the monomer (M-5) were dissolved in 200 g of 2-butanone, and 3.38 g of dimethyl azobisisobutyronitrile was added to the solution to prepare a monomer solution. A three-necked flask (500 ml) charged with 100 g of 2-butanone was purged with nitrogen for 30 minutes, and then heated to 80° C. with stirring. The monomer solution was added dropwise to the flask over three hours using a dropping funnel. The monomers were polymerized for six hours from the start of the addition of the monomer solution. The polymer solution was then cooled with water to 30° C. or less, and poured into 2000 g of methanol. A white powdery precipitate was collected by filtration. The collected white powder was washed twice with 400 g of methanol in a slurry state, collected by filtration, and dried at 50° C. for 17 hours to obtain a white powdery copolymer (yield: 66.3%).

The polymer was a copolymer having an Mw of 7500 and an Mw/Mn ratio of 1.35. The ratio of the repeating units derived from the monomers (M-1), (M-6), and (M-5) determined by ¹³C-NMR analysis was 47.2:7.5:45.3 (mol %). This polymer is referred to as “resin (A-1)”. The content of low-molecular-weight components derived from the monomers in the resin (A-1) was less than 0.1 mass %.

### <Synthesis of Resins (A-2) to (A-11)>

Resins (A-2) to (A-11) were synthesized in the same manner as the resin (A-1), except for changing the types and the amounts of monomers as shown in Table 1. The Mw, the Mw/Mn ratio (molecular weight dispersity), and the yield (mass %) of each polymer, and the ratio of repeating units included in each polymer were measured. The results are shown in Table 1.

Note that the resins (A-1) to (A-7) correspond to the resin (A1), and the resins (A-8) to (A-11) correspond to the resin (A2).

TABLE 1

| | | | Monomer 1 | | Monomer 2 | | Monomer 3 | | Monomer 4 | | |
|---|---|---|---|---|---|---|---|---|---|---|---|
| | | | | Amount | | Amount | | Amount | | Amount | Initiator |
| | | Polymer | Type | (mol %) | Type | (mol %) | Type | (mol %) | Type | (mol %) | (mol %) |
| Polymerization | 1 | A-1 | M-1 | 50 | M-6 | 10 | M-5 | 40 | — | — | 5 |
| Example | 2 | A-2 | M-2 | 15 | M-3 | 35 | M-6 | 10 | M-5 | 40 | 5 |
| | 3 | A-3 | M-1 | 30 | M-4 | 10 | M-6 | 10 | M-5 | 50 | 5 |
| | 4 | A-4 | M-1 | 30 | M-4 | 10 | M-7 | 10 | M-5 | 50 | 5 |
| | 5 | A-5 | M-1 | 30 | M-4 | 10 | M-7 | 20 | M-5 | 40 | 5 |
| | 6 | A-6 | M-1 | 30 | M-4 | 10 | M-8 | 15 | M-5 | 45 | 5 |
| | 7 | A-7 | M-1 | 30 | M-4 | 10 | M-9 | 15 | M-5 | 45 | 5 |
| | 8 | A-8 | M-1 | 50 | M-5 | 50 | — | — | — | — | 5 |
| | 9 | A-9 | M-2 | 15 | M-3 | 35 | M-5 | 50 | — | — | 5 |
| | 10 | A-10 | M-1 | 40 | M-4 | 10 | M-5 | 50 | — | — | 5 |
| | 11 | A-11 | M-3 | 60 | M-10 | 40 | — | — | — | — | 5 |

TABLE 2

| | | | | Content (mol %) of repeating unit | | | | | | |
|---|---|---|---|---|---|---|---|---|---|---|
| | | | | derived from each monomer | | | | Low-molecular- | | |
| | | | | Monomer | Monomer | Monomer | Monomer | weight | | |
| | | Polymer | Yield (%) | 1 | 2 | 3 | 4 | component (%) | Mw | Mw/Mn |
| Polymerization | 1 | A-1 | 66.3 | 47.2 | 7.5 | 45.3 | — | <0.1 | 7500 | 1.35 |
| Example | 2 | A-2 | 64.5 | 14.1 | 32.9 | 9.2 | 43.8 | <0.1 | 6800 | 1.38 |
| | 3 | A-3 | 64.2 | 31.0 | 9.8 | 8.5 | 50.7 | <0.1 | 6900 | 1.39 |
| | 4 | A-4 | 65.5 | 30.5 | 9.7 | 8.8 | 51.0 | <0.1 | 6700 | 1.60 |
| | 5 | A-5 | 62.0 | 32.3 | 9.7 | 18.5 | 39.5 | <0.1 | 7300 | 1.35 |
| | 6 | A-6 | 65.7 | 30.7 | 9.2 | 14.2 | 45.9 | <0.1 | 7400 | 1.40 |
| | 7 | A-7 | 65.1 | 31.2 | 8.8 | 14.0 | 46.0 | <0.1 | 6500 | 1.30 |
| | 8 | A-8 | 68.4 | 50.2 | 49.8 | — | — | <0.1 | 7200 | 1.45 |
| | 9 | A-9 | 76.0 | 14.3 | 35.2 | 50.5 | — | <0.1 | 6800 | 1.55 |
| | 10 | A-10 | 75.0 | 40.0 | 8.9 | 51.1 | — | <0.1 | 6500 | 1.45 |
| | 11 | A-11 | 65.0 | 59.0 | 41.0 | — | — | <0.1 | 5500 | 1.40 |

### <Production of Radiation-Sensitive Resin Composition>

Radiation-sensitive resin compositions of Examples 1 to 13 and Comparative Examples 1 to 5 were produced by mixing the resin component (A) (resins (A1) and (A2)), the acid generator (B), the nitrogen-containing compound (D), and the solvent (C) in a ratio shown in Tables 3 and 4.

TABLE 3

| | | Resin component (A) | | | Nitrogen-containing | | |
|---|---|---|---|---|---|---|---|
| | | Resin (A1) | Resin (A2) | Acid generator | compound (D) | Solvent (C) | |
| | | (type (parts)) | (type (parts)) | (B) (type (parts)) | (type (parts)) | (type (parts)) | |
| Example | 1 | A-2 (100) | — | B-1 (4.0) | D-1 (0.70) | C-1 | (1700) |
| | | | | B-2 (3.6) | | C-2 | (700) |
| | | | | | | C-3 | (30) |
| | 2 | A-3 (100) | — | B-1 (4.0) | D-1 (0.90) | C-1 | (1700) |
| | | | | B-2 (3.6) | | C-2 | (700) |
| | | | | | | C-3 | (30) |
| | 3 | A-4 (100) | — | B-1 (4.0) | D-1 (0.90) | C-1 | (1700) |
| | | | | B-2 (3.6) | | C-2 | (700) |
| | | | | | | C-3 | (30) |
| | 4 | A-6 (100) | — | B-1 (4.0) | D-1 (0.80) | C-1 | (1700) |
| | | | | B-2 (3.6) | | C-2 | (700) |
| | | | | | | C-3 | (30) |
| | 5 | A-7 (100) | — | B-1 (4.0) | D-1 (0.85) | C-1 | (1700) |
| | | | | B-2 (3.6) | | C-2 | (700) |
| | | | | | | C-3 | (30) |
| | 6 | A-3 (100) | — | B-3 (7.5) | D-1 (0.90) | C-1 | (1700) |
| | | | | | | C-2 | (700) |
| | | | | | | C-3 | (30) |
| | 7 | A-4 (100) | — | B-3 (7.5) | D-1 (0.90) | C-1 | (1700) |
| | | | | | | C-2 | (700) |
| | | | | | | C-3 | (30) |
| | 8 | A-1 (100) | — | B-1 (4.0) | D-1 (0.70) | C-1 | (1700) |
| | | | | B-2 (3.6) | | C-2 | (700) |
| | | | | | | C-3 | (30) |
| | 9 | A-2 (100) | — | B-1 (4.0) | D-1 (0.65) | C-1 | (1700) |
| | | | | B-2 (3.6) | | C-2 | (700) |
| | | | | | | C-3 | (30) |

TABLE 4

| | | Resin component (A) | | | Nitrogen-containing | | |
|---|---|---|---|---|---|---|---|
| | | Resin (A1) | Resin (A2) | Acid generator | compound (D) | Solvent (C) | |
| | | (type (parts)) | (type (parts)) | (B) (type (parts)) | (type (parts)) | (type (parts)) | |
| Example | 10 | A-5 (100) | — | B-1 (4.0) | D-1 (0.80) | C-1 | (1700) |
| | | | | B-2 (3.6) | | C-2 | (700) |
| | | | | | | C-3 | (30) |
| | 11 | A-6 (100) | — | B-1 (4.0) | D-1 (0.80) | C-1 | (1700) |
| | | | | B-2 (3.6) | | C-2 | (700) |
| | | | | | | C-3 | (30) |
| | 12 | A-2 (70) | A-9 (30) | B-1 (4.0) | D-1 (0.65) | C-1 | (1700) |
| | | | | B-2 (3.6) | | C-2 | (700) |
| | | | | | | C-3 | (30) |
| | 13 | A-2 (80) | A-9 (20) | B-1 (4.0) | D-1 (0.65) | C-1 | (1700) |
| | | | | B-2 (3.6) | | C-2 | (700) |
| | | | | | | C-3 | (30) |
| Comparative | 1 | — | A-9 (100) | B-1 (4.0) | D-1 (0.70) | C-1 | (1700) |
| Example | | | | B-2 (3.6) | | C-2 | (700) |
| | | | | | | C-3 | (30) |
| | 2 | — | A-10 (100) | B-1 (4.0) | D-1 (0.90) | C-1 | (1700) |
| | | | | B-2 (3.6) | | C-2 | (700) |
| | | | | | | C-3 | (30) |
| | 3 | — | A-8 (100) | B-1 (4.0) | D-1 (0.70) | C-1 | (1700) |
| | | | | B-2 (3.6) | | C-2 | (700) |
| | | | | | | C-3 | (30) |
| | 4 | — | A-9 (100) | B-1 (4.0) | D-1 (0.70) | C-1 | (1700) |
| | | | | B-2 (3.6) | | C-2 | (700) |
| | | | | | | C-3 | (30) |
| | 5 | — | A-9 (90) | B-1 (4.0) | D-1 (0.70) | C-1 | (1700) |
| | | | A-11 (10) | B-2 (3.6) | | C-2 | (700) |
| | | | | | | C-3 | (30) |

The acid generator (B), the nitrogen-containing compound (D), and the solvent (C) shown in Tables 3 and 4 are as follows. In each table, the unit “parts” refers to “parts by mass” unless otherwise indicated.

### <Acid Generator (B)>

(B-1): triphenylsulfonium nonafluoro-n-butanesulfonate
(B-2): triphenylsulfonium 2-(bicyclo[2.2.1]hept-2′-yl)-1,1-difluoroethanesulfonate
(B-3): triphenylsulfonium 2-(bicyclo[2.2.1]hept-2′-yl)-1,1,2,2-tetrafluoroethanesulfonate

### <Nitrogen-Containing Compound (D)>

(D-1): N-t-butoxycarbonyl-4-hydroxypiperidine

### <Solvent (C)>

(C-1): propylene glycol monomethyl ether acetate
(C-2): cyclohexanone
(C-3): γ-butyrolactone

### <Evaluation of Radiation-Sensitive Resin Composition>

The radiation-sensitive resin compositions of Examples 1 to 13 and Comparative Examples 1 to 5 were evaluated as follows. The evaluation results are shown in Tables 5 and 6.

### <Sensitivity>

A silicon wafer on which an ARC29 (manufactured by Nissan Chemical Industries, Ltd.) film (thickness: 770 angstroms) was formed, was used. The composition solution was spin-coated onto the silicon wafer using an instrument “Clean Track ACT8” (manufactured by Tokyo Electron, Ltd.), and prebaked (PB) on a hot plate under conditions shown in Tables 5 and 6 to obtain a resist film having a thickness of 0.12 μm.

When using the composition solutions of Examples 8 to 13 and Comparative Examples 3 to 5, the resist film was rinsed with purified water for 90 seconds. When using the composition solutions of Examples 1 to 7 and Comparative Examples 1 and 2, a liquid immersion lithography upperlayer film (“NFC TCX041” manufactured by JSR Corporation) (thickness: 0.09 μm) was formed on the resist film by spin coating, baked at 90° C. for 60 seconds, and rinsed with purified water for 90 seconds.

The resulting resist film was exposed via a mask pattern using an ArF excimer laser exposure system (“S306C” manufactured by Nikon Corporation) (numerical aperture: 0.78). The resist film was then rinsed with purified water for 90 seconds. After performing PEB under conditions shown in Tables 5 and 6, the resist film was developed at 23° C. for 60 seconds using a 2.38 mass % tetramethylammonium hydroxide aqueous solution, washed with water, and dried to form a positive-tone resist pattern. An optimum dose at which a line-and-space pattern (1L1S) having a diameter of 0.075 μm was formed was taken as the sensitivity.

### <Exposure Latitude (EL)>

The size of the line pattern of the 0.075 micrometer line-and-space pattern (refer to the measurement of sensitivity) when changing the dose by 1.0 mJ/cm² within the range of optimum dose±10 mJ/cm² was plotted, and the slope of the resulting graph was taken as the exposure latitude (EL) (nm/mJ).

### <Minimum Collapse Dimensions (Collapse)>

The CD dimensions at a dose lower by 1 mJ than the dose at which the line of the 0.075 micrometer line-and-space pattern (refer to the measurement of the sensitivity) collapsed were measured using a CD-SEM (“S-9380” manufactured by Hitachi Ltd.).

A case where the CD dimensions were 50 nm or less was evaluated as “Good”.

### <Cross-Sectional Pattern Shape (Pattern Shape)>

The cross-sectional shape of the 0.075 micrometer line-and-space pattern (refer to the measurement of the sensitivity) was observed using a scanning electron microscope (“S-4800” manufactured by Hitachi High-Technologies Corporation). A case where the line-and-space pattern had a T-top shape or a round-top shape (i.e., a shape other than a rectangular shape) was evaluated as “Bad”, and a case where the line-and-space pattern had a rectangular shape was evaluated as “Good”.

### <Elution Volume>

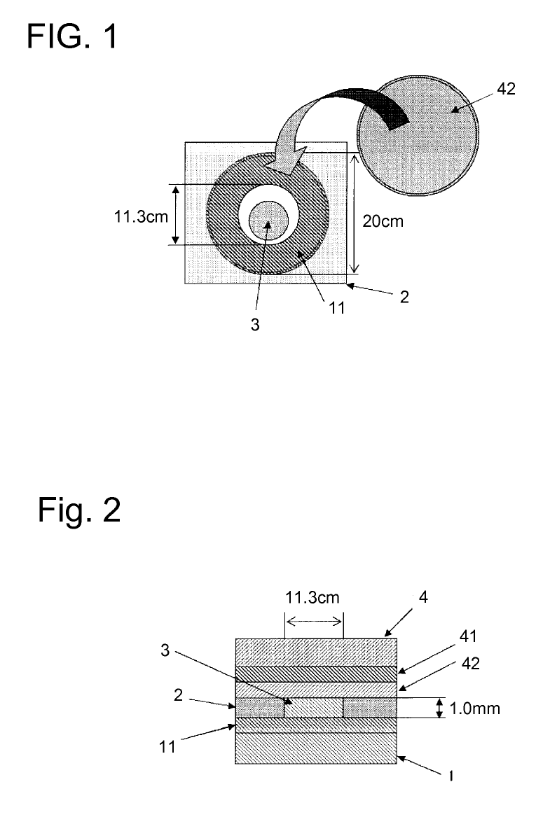

As shown in FIG. 1, a square (30×30 cm) silicone rubber sheet 2 (manufactured by Kureha Elastomer Co., Ltd., thickness: 1.0 mm) having a circular opening (diameter: 11.3 cm) at the center was placed at the center of an 8-inch silicon wafer 1 that was treated with hexamethyldisilazane (HMDS) (100° C., 60 sec) using a coater/developer “CLEAN TRACK ACT8” (manufactured by Tokyo Electron, Ltd.). The center opening of the silicone rubber sheet 2 was filled with 10 ml of ultrapure water 3 using a 10 ml whole pipette.

Reference numeral 11 in FIG. 1 indicates a hexamethyldisilazane-treated layer.

As shown in FIG. 2, an underlayer antireflective film (“ARC29A” manufactured by Bruwer Science) 41 (thickness: 77 nm) was formed using the coater/developer. The radiation-sensitive resin composition (Examples 8 to 13 and Comparative Examples 3 to 5) was spin-coated onto the underlayer antireflective film 41 using the coater/developer, and baked (PEB) under conditions shown in Tables 5 and 6 to form a resist film 42 (thickness: 205 nm). The silicon wafer 4 was placed on the silicone rubber sheet 2 so that the surface of the resist film came in contact with the ultrapure water 3, and the ultrapure water 3 did not leak from the silicon sheet 2.

After 10 seconds, the silicon wafer 4 was removed, and the ultrapure water 3 was collected using a glass syringe to obtain an analysis sample. The recovery rate of the ultrapure water 3 was 95% or more.

The peak intensity of the anion site of the acid generator included in the ultrapure water was measured under the following conditions using a liquid chromatograph mass spectrometer (LC-MS) (LC section: “SERIES 1100” manufactured by AGILENT Corp., MS section: “Mariner” manufactured by PerSeptive Biosystems, Inc.). The peak intensity of an aqueous solution (1 ppb, 10 ppb, or 100 ppb) of the acid generator was measured under the following measurement conditions, and a calibration curve was drawn. The elution volume was calculated from the peak intensity using the calibration curve. Likewise, the peak intensity of an aqueous solution (1 ppb, 10 ppb, or 100 ppb) of the nitrogen-containing compound (D-1) was measured under the following measurement conditions, and a calibration curve was drawn. The elution volume of the acid diffusion controller was calculated from the peak intensity using the calibration curve. A case where the elution volume was 5.0×10⁻¹² mol/cm²/sec or more was evaluated as “Bad”, and a case where the elution volume was less than 5.0×10⁻¹² mol/cm²/sec was evaluated as “Good”.

### (Measurement Conditions)

Column: CAPCELL PAK MG manufactured by Shiseido Co., Ltd.
Flow rate: 0.2 ml/min
Eluant: prepared by adding 0.1 mass % of formic acid to a water/methanol (volume ratio: 3:7) mixture
Measurement temperature: 35° C.

### <Receding Contact Angle>

A film of the radiation-sensitive resin composition (Examples 8 to 13 and Comparative Examples 3 to 5) was formed on a substrate (wafer). The receding contact angle was immediately measured by the following method at a temperature of 23° C. (room temperature) and a humidity of 45% under atmospheric pressure using a contact angle meter (“DSA-10” manufactured by KRUS).

Specifically, the position of the wafer stage of the contact angle meter was adjusted, and the substrate was placed on the stage. After injecting water into the needle, the position of the needle was adjusted to the initial position at which a waterdrop can be formed on the substrate. Water was discharged from the needle to form a waterdrop (25 μl) on the substrate. After removing the needle, the needle was moved downward to the initial position, and introduced into the waterdrop. The waterdrop was sucked through the needle for 90 seconds at a rate of 10 μl/min, and the contact angle formed by the liquid surface and the substrate was measured every second (90 times in total). The average value of twenty contact angle measured values (20 seconds) after the measured value became stable was calculated, and taken as the receding contact angle (°).

TABLE 5

| | | | | Liquid | | | | | | |
|---|---|---|---|---|---|---|---|---|---|---|
| | | | | immersion | | | Minimum | | | |
| | | | | lithography | | | collapse | | Receding | |
| | | PB | PEB | upperlayer | Sensitivity | EL | dimensions | Elution | contact | Pattern |
| | | (temp./time) | (temp./time) | film | (mJ) | (nm/mJ) | (nm) | volume | angle (°) | shape |
| Example | 1 | 120° C./60 sec | 105° C./60 sec | Formed | 55 | 1.6 | 47 | — | — | Good |
| | 2 | 120° C./60 sec | 95° C./60 sec | Formed | 57 | 1.5 | 49 | — | — | Good |
| | 3 | 120° C./60 sec | 95° C./60 sec | Formed | 54 | 1.6 | 47 | — | — | Good |
| | 4 | 120° C./60 sec | 95° C./60 sec | Formed | 55 | 1.6 | 48 | — | — | Good |
| | 5 | 120° C./60 sec | 95° C./60 sec | Formed | 53 | 1.7 | 47 | — | — | Good |
| | 6 | 120° C./60 sec | 95° C./60 sec | Formed | 57 | 1.6 | 45 | — | — | Good |
| | 7 | 120° C./60 sec | 95° C./60 sec | Formed | 54 | 1.6 | 45 | — | — | Good |
| | 8 | 120° C./60 sec | 120° C./60 sec | Not formed | 50 | 1.7 | 49 | Good | 75 | Good |
| | 9 | 120° C./60 sec | 105° C./60 sec | Not formed | 56 | 1.6 | 48 | Good | 76 | Good |
| | 10 | 120° C./60 sec | 95° C./60 sec | Not formed | 54 | 1.5 | 47 | Good | 72 | Good |
| | 11 | 120° C./60 sec | 95° C./60 sec | Not formed | 54 | 1.5 | 48 | Good | 73 | Good |
| | 12 | 120° C./60 sec | 105° C./60 sec | Not formed | 57 | 1.6 | 48 | Good | 71 | Good |
| | 13 | 120° C./60 sec | 105° C./60 sec | Not formed | 57 | 1.5 | 49 | Good | 74 | Good |

TABLE 6

| | | | | Liquid | | | | | | |
|---|---|---|---|---|---|---|---|---|---|---|
| | | | | immersion | | | Minimum | | | |
| | | | | lithography | | | collapse | | Receding | |
| | | PB | PEB | upperlayer | Sensitivity | EL | dimensions | Elution | contact | Pattern |
| | | (temp./time) | (temp./time) | film | (mJ) | (nm/mJ) | (nm) | volume | angle (°) | shape |
| Comparative | 1 | 120° C./60 sec | 105° C./60 sec | Formed | 55 | 1.6 | 55 | — | — | Good |
| Example | 2 | 120° C./60 sec | 95° C./60 sec | Formed | 55 | 1.7 | 53 | — | — | Good |
| | 3 | 120° C./60 sec | 120° C./60 sec | Not formed | 52 | 1.6 | 60 | Bad | 61 | Bad |
| | 4 | 120° C./60 sec | 105° C./60 sec | Not formed | 58 | 1.5 | 62 | Bad | 61 | Bad |
| | 5 | 120° C./60 sec | 105° C./60 sec | Not formed | 56 | 1.6 | 59 | Good | 78 | Bad |

As is clear from Tables 5 and 6, the resin compositions of the examples produced using the resin including the repeating unit (a1) including a fluorine atom and an acid-dissociable group in its side chain exhibited excellent pattern collapse resistance (minimum collapse dimensions) without showing a deterioration in EL performance. Since the resin compositions of the examples have excellent water repellency due to the repeating unit (a1), the resin compositions of the examples are expected to exhibit excellent performance during liquid immersion lithography regardless of the presence or absence of a liquid immersion lithography upperlayer film.

According to the embodiment of the present invention, the radiation-sensitive resin composition exhibits excellent basic performance (e.g., transparency to radiation and sensitivity) as a chemically-amplified resist that responds to deep ultraviolet rays such as ArF excimer laser light (wavelength 193 nm), exhibits excellent exposure latitude (EL) when forming a line pattern, produces an excellent pattern shape, and exhibits small minimum collapse dimensions (collapse) when forming a line pattern (L/S pattern).

The radiation-sensitive resin composition may be suitably used for liquid immersion lithography (e.g., liquid immersion lithography that forms a resist pattern by applying radiation via an immersion liquid (e.g., water) that has a refractive index higher than that of air at a wavelength of 193 nm, or liquid immersion lithography that forms a resist pattern without forming a protective film on a resist film), reduces the elution volume upon contact with an immersion liquid (e.g., water) during liquid immersion lithography, increases the receding contact angle formed by the resist film and the immersion liquid (e.g., water), and improves the solubility of the exposed area in a developer (i.e., suppresses development defects). Moreover, a variation in pattern shape during liquid immersion lithography can be reduced.

Therefore, the radiation-sensitive resin composition may be suitably used for production of semiconductor devices that are expected to be further miniaturized.

Obviously, numerous modifications and variations of the present invention are possible in light of the above teachings. It is therefore to be understood that within the scope of the appended claims, the invention may be practiced otherwise than as specifically described herein.

1. A radiation-sensitive resin composition for liquid immersion lithography, comprising:
a resin component comprising:
an acid-dissociable group-containing resin in an amount of more than 50% by mass, the acid-dissociable group-containing resin including a repeating unit that includes a fluorine atom and an acid-dissociable group in a side chain of the repeating unit;
a photoacid generator; and
a solvent.

2. The radiation-sensitive resin composition according to claim 1, wherein the acid-dissociable group-containing resin includes a repeating unit shown by a following formula (1) as the repeating unit, 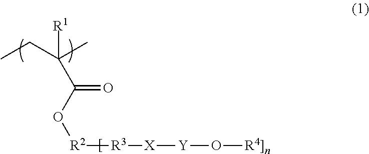
wherein n is an integer from 1 to 3, R¹ represents a hydrogen atom, a methyl group, or a trifluoromethyl group, R² represents a single bond or a linear, branched, or cyclic saturated or unsaturated (n+1)-valent hydrocarbon group having 1 to 10 carbon atoms, R³ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, Y represents a single bond or —CO—, and R⁴ represents an acid-dissociable group when n is 1, or individually represent a hydrogen atom or an acid-dissociable group when n is 2 or 3, provided that at least one of R⁴ represents an acid-dissociable group.

3. The radiation-sensitive resin composition according to claim 2, wherein the acid-dissociable group-containing resin includes a repeating unit shown by a following formula (1-1) as the repeating unit shown by the formula (1), 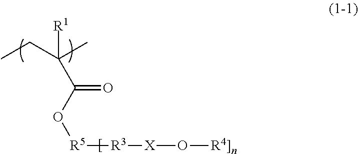
wherein n is an integer from 1 to 3, R¹ represents a hydrogen atom, a methyl group, or a trifluoromethyl group, R³ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, R⁴ represents an acid-dissociable group when n is 1, or individually represent a hydrogen atom or an acid-dissociable group when n is 2 or 3, provided that at least one of R⁴ represents an acid-dissociable group, and R⁵ represents a linear, branched, or cyclic saturated or unsaturated (n+1)-valent hydrocarbon group having 3 to 10 carbon atoms.

4. The radiation-sensitive resin composition according to claim 2, wherein the acid-dissociable group-containing resin includes a repeating unit shown by a following formula (1-2) as the repeating unit shown by the formula (1), 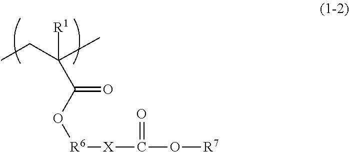
wherein R¹ represents a hydrogen atom, a methyl group, or a trifluoromethyl group, R⁶ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, and R⁷ represents an acid-dissociable group.

5. The radiation-sensitive resin composition according to claim 2, wherein the acid-dissociable group-containing resin includes a repeating unit shown by a following formula (1-3) as the repeating unit shown by the formula (1), 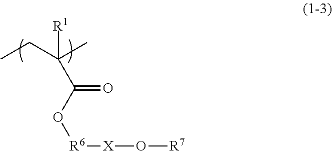
wherein R¹ represents a hydrogen atom, a methyl group, or a trifluoromethyl group, R⁶ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, and R⁷ represents an acid-dissociable group.

6. A resist pattern-forming method comprising:
forming a photoresist film on a substrate using the radiation-sensitive resin composition according to claim 1;
subjecting the photoresist film to liquid immersion lithography; and
developing the photoresist film subjected to liquid immersion lithography to form a resist pattern.

7. A polymer comprising a first repeating unit shown by a following formula (1), and a second repeating unit that includes a lactone skeleton, 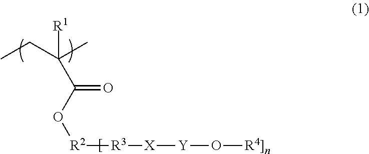
wherein n is an integer from 1 to 3, R¹ represents a hydrogen atom, a methyl group, or a trifluoromethyl group, R² represents a single bond or a linear, branched, or cyclic saturated or unsaturated (n+1)-valent hydrocarbon group having 1 to 10 carbon atoms, R³ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, Y represents a single bond or —CO—, and R⁴ represents an acid-dissociable group when n is 1, or individually represent a hydrogen atom or an acid-dissociable group when n is 2 or 3, provided that at least one of R⁴ represents an acid-dissociable group.

8. The radiation-sensitive resin composition according to claim 3, wherein the acid-dissociable group-containing resin includes a repeating unit shown by a following formula (1-2) as the repeating unit shown by the formula (1), 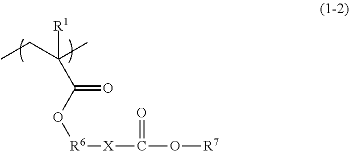
wherein R¹ represents a hydrogen atom, a methyl group, or a trifluoromethyl group, R⁶ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, and R⁷ represents an acid-dissociable group.

9. The radiation-sensitive resin composition according to claim 3, wherein the acid-dissociable group-containing resin includes a repeating unit shown by a following formula (1-3) as the repeating unit shown by the formula (1), 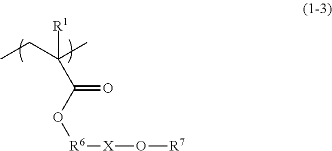
wherein R¹ represents a hydrogen atom, a methyl group, or a trifluoromethyl group, R⁶ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, and R⁷ represents an acid-dissociable group.

10. The radiation-sensitive resin composition according to claim 4, wherein the acid-dissociable group-containing resin includes a repeating unit shown by a following formula (1-3) as the repeating unit shown by the formula (1), 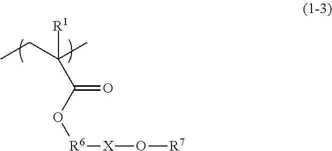
wherein R¹ represents a hydrogen atom, a methyl group, or a trifluoromethyl group, R⁶ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, and R⁷ represents an acid-dissociable group.

11. The radiation-sensitive resin composition according to claim 8, wherein the acid-dissociable group-containing resin includes a repeating unit shown by a following formula (1-3) as the repeating unit shown by the formula (1), 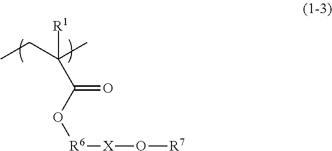
wherein R¹ represents a hydrogen atom, a methyl group, or a trifluoromethyl group, R⁶ represents a single bond or a linear, branched, or cyclic saturated or unsaturated divalent hydrocarbon group having 1 to 20 carbon atoms, X represents a methylene group substituted with a fluorine atom or a linear or branched fluoroalkylene group having 2 to 20 carbon atoms, and R⁷ represents an acid-dissociable group.

12. A resist pattern-forming method comprising:
forming a photoresist film on a substrate using the radiation-sensitive resin composition according to claim 2;
subjecting the photoresist film to liquid immersion lithography; and
developing the photoresist film subjected to liquid immersion lithography to form a resist pattern.

13. A resist pattern-forming method comprising:
forming a photoresist film on a substrate using the radiation-sensitive resin composition according to claim 3;
subjecting the photoresist film to liquid immersion lithography; and
developing the photoresist film subjected to liquid immersion lithography to form a resist pattern.

14. A resist pattern-forming method comprising:
forming a photoresist film on a substrate using the radiation-sensitive resin composition according to claim 4;
subjecting the photoresist film to liquid immersion lithography; and
developing the photoresist film subjected to liquid immersion lithography to form a resist pattern.

15. A resist pattern-forming method comprising:
forming a photoresist film on a substrate using the radiation-sensitive resin composition according to claim 5;
subjecting the photoresist film to liquid immersion lithography; and
developing the photoresist film subjected to liquid immersion lithography to form a resist pattern.

16. A resist pattern-forming method comprising:
forming a photoresist film on a substrate using the radiation-sensitive resin composition according to claim 8;
subjecting the photoresist film to liquid immersion lithography; and
developing the photoresist film subjected to liquid immersion lithography to form a resist pattern.

17. A resist pattern-forming method comprising:
forming a photoresist film on a substrate using the radiation-sensitive resin composition according to claim 9;
subjecting the photoresist film to liquid immersion lithography; and
developing the photoresist film subjected to liquid immersion lithography to form a resist pattern.

18. A resist pattern-forming method comprising:
forming a photoresist film on a substrate using the radiation-sensitive resin composition according to claim 10;
subjecting the photoresist film to liquid immersion lithography; and
developing the photoresist film subjected to liquid immersion lithography to form a resist pattern.

19. A resist pattern-forming method comprising:
forming a photoresist film on a substrate using the radiation-sensitive resin composition according to claim 11;
subjecting the photoresist film to liquid immersion lithography; and
developing the photoresist film subjected to liquid immersion lithography to form a resist pattern.
